(19) United States
(12) Patent Application Publication
(10) Pub. No.: US 2024/0027923 A1
(43) Pub. Date: Jan. 25, 2024

(54) SUBSTRATE PROCESSING APPARATUS, SUBSTRATE PROCESSING METHOD, AND RECORDING MEDIUM

(71) Applicant: Tokyo Electron Limited, Tokyo (JP)

(72) Inventors: Tomoya ONITSUKA, Koshi City (JP); Shinichiro KAWAKAMI, Koshi City (JP); Hisashi GENJIMA, Koshi City (JP)

(21) Appl. No.: 18/353,300

(22) Filed: Jul. 17, 2023

(30) Foreign Application Priority Data
Jul. 22, 2022 (JP) 2022-116959
Apr. 27, 2023 (JP) 2023-073304

(51) Int. Cl. G03F 7/00

(52) U.S. Cl. CPC G03F 7/70866

(57) ABSTRACT

A substrate processing apparatus for processing a substrate including a metal-containing resist film, includes: a heat treatment part configured to perform a heat treatment on the substrate having the film subjected to an exposing process; a developing process part configured to perform a developing process on the film of the substrate subjected to the heat treatment; and a gas contact part configured to bring the film into contact with an inert gas during a period after the exposing process and before the developing process.

### CROSS-REFERENCE TO RELATED APPLICATIONS

This application is based upon and claims the benefit of priority from Japanese Patent Application Nos. 2022-116959 and 2023-073304, filed on Jul. 22, 2022 and Apr. 27, 2023, respectively, the entire contents of which are incorporated herein by reference.

### TECHNICAL FIELD

The present disclosure relates to a substrate processing apparatus, a substrate processing method, and a non-transitory computer-readable recording medium.

### BACKGROUND

Patent Document 1 discloses a configuration in which an adjustment controller is provided to reduce a difference in amounts of moisture that reacts with a film of each substrate when performing a heat treatment with respect to the film formed using a metal-containing resist.

### [Prior Art Document]

### [Patent Document]

Patent Document 1: Japanese Laid-Open Patent Publication No. 2020-119961

### SUMMARY

According to one embodiment of the present disclosure, there is provided a substrate processing apparatus for processing a substrate including a metal-containing resist film, includes: a heat treatment part configured to perform a heat treatment on the substrate having the film subjected to an exposing process; a developing process part configured to perform a developing process on the film of the substrate subjected to the heat treatment; and a gas contact part configured to bring the film into contact with an inert gas during a period after the exposing process and before the developing process.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a schematic configuration of a substrate processing system according to an exemplary embodiment.

FIG. 2 is a schematic diagram illustrating an internal configuration of a substrate processing apparatus;

FIG. 3 is a schematic diagram illustrating a configuration corresponding to a view taken along line in FIG. 2.

FIG. 4 is a schematic diagram illustrating an example of a gas supply unit.

FIG. 5 is a schematic diagram illustrating an example of a heat treatment unit.

FIG. 6 is a schematic diagram illustrating an example of a temperature adjustment unit.

FIG. 7 is a functional block diagram illustrating an example of a functional configuration of a control device.

FIG. 8 is a diagram illustrating an example of a substrate transfer route.

FIG. 9 is a block diagram illustrating an example of a hardware configuration of the control device.

FIG. 10 is a flowchart illustrating an example of a substrate processing method.

FIGS. 11A and 11B are diagrams illustrating a modification of the configuration of the gas contact part.

FIGS. 12A and 12B are diagrams illustrating a modification of the configuration of the gas contact part.

FIG. 13 is a flowchart illustrating another example of the substrate processing method.

FIG. 14 is a schematic diagram illustrating an internal configuration of a coating developing apparatus according to a modification.

FIG. 15 is a schematic diagram illustrating a configuration corresponding to a view taken along line XV-XV in FIG. 14.

### DETAILED DESCRIPTION

Various exemplary embodiments will be described below. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In an exemplary embodiment, a substrate processing apparatus is provided. The substrate processing apparatus, which is used for processing a substrate including a metal-containing resist film, includes: a heat treatment part configured to perform a heat treatment on the substrate having the film subjected to an exposing process; a developing process part configured to perform a developing process on the film of the substrate subjected to the heat treatment; and a gas contact part configured to bring the film into contact with an inert gas during a period after the exposing process and before the developing process.

In the substrate processing apparatus described above, the film is brought into contact with the inert gas in the gas contact part. Therefore, the time during which the metal-containing resist film is in contact with the ambient atmosphere may be shortened as compared with a case where the gas contact part is not provided.

In an aspect, the gas contact part may be a gas processing unit configured to temporarily place the substrate in a predetermined housing and including a gas supply part for supplying the gas into the housing, and may be provided in an interface block.

With the above configuration, the film may be brought into contact with the inert gas by transferring the substrate into the gas processing unit. Further, when the gas processing unit is provided in the interface block, the substrate may be transferred to the gas processing unit while the substrate is being transferred to and from the exposure apparatus. Therefore, it is possible to shorten the time required to transfer the substrate to the gas processing unit, which makes it possible to reduce the time during which the substrate is exposed to the ambient atmosphere.

In an aspect, the heat treatment part may include a hot plate configured to heat the substrate, and a temperature adjustment plate configured to hold the substrate subjected to the heat treatment on the hot plate, and the gas contact part may include a second gas supply part configured to supply the inert gas so that the temperature adjustment plate of the heat treatment part and the film of the substrate on the temperature adjustment plate are in contact with the inert gas.

With the above configuration, in the heat treatment part, the film of the substrate held by the temperature adjustment plate subjected to the heat treatment may also be brought into contact with the inert gas.

In an aspect, the gas contact part may further include a chamber configured to surround the temperature adjustment plate so that the inert gas supplied from the second gas supply part contacts the film.

By adopting the configuration in which the temperature adjustment plate is surrounded by the chamber as described above, it becomes easier for the inert gas supplied from the second gas supply part to come into contact with the film.

In an aspect, the gas contact part may be a temperature adjustment unit configured to temporarily hold the substrate unloaded from the heat treatment part before the substrate is loaded into the developing process part, and may include a third gas supply part configured to supply the inert gas into the temperature adjustment unit.

With the above configuration, it is possible to bring the film of the substrate into contact with the inert gas even in the temperature adjustment unit. This makes it possible to reduce the time during which the substrate is exposed to the ambient atmosphere.

In an aspect, the substrate processing apparatus may further include: a control part configured to control the contact period of the substrate in the gas contact part and the transfer of the substrate to the gas contact part.

With the above configuration, the control part may control the contact period of the substrate in the gas contact part and the transfer of the substrate to the gas contact part. For example, while adjusting the transfer path of multiple substrates and the like, it is possible to shorten the time during which the metal-containing resist film on each substrate is in contact with the ambient atmosphere.

In an aspect, the gas contact part may be a gas processing unit configured to temporarily place the substrate in a predetermined housing and including a gas supply part for supplying the gas into the housing, the gas contact part may be provided in an interface block, and the control part may perform control to transfer the substrate to the gas processing unit and to bring the film into contact with the inert gas in the gas processing unit for a predetermined time.

With the above configuration, the film may be brought into contact with the inert gas by transferring the substrate to the gas processing unit by the control part.

In an aspect, the heat treatment part may include a hot plate configured to heat the substrate, a temperature adjustment plate configured to hold the substrate subjected to the heat treatment on the hot plate, and a second gas supply part configured to supply the inert gas so that the film of the substrate on the temperature adjustment plate that is in contact with the inert gas, and the control part may be configured to perform control to bring the film of the substrate unloaded from the gas processing unit into contact with the inert gas for a predetermined time on the temperature adjustment plate of the heat treatment part.

With the above configuration, the film may be brought into contact with the inert gas by causing the substrate to wait on the temperature adjustment plate by the control part.

In an aspect, the substrate processing apparatus may further include: a temperature adjustment unit configured to temporarily hold the substrate unloaded from the heat treatment part before loading the substrate into the developing process part, wherein the temperature adjustment unit may include a third gas supply part configured to supply the inert gas into the temperature adjustment unit, and the control part may be configured to perform control to bring the film of the substrate unloaded from the heat treatment part into contact with the inert gas for a predetermined time in the temperature adjustment unit.

With the above configuration, the film may be brought into contact with the inert gas by transferring the substrate to the temperature adjustment unit by the control part.

In as aspect, the gas contact part may include a substrate holding part configured to hold the substrate, an enclosing part configured to surround the upper side and the lateral side of the substrate holding part, and a gas supply port configured to supply the inert gas into the enclosing part from above the enclosing part, and the gas contact part may be configured to supply the inert gas into the enclosing part to push an internal atmosphere downward to thereby bring the inert gas into contact with the substrate held by the substrate holding part.

With the above configuration, the inert gas supplied into the enclosing part from above the enclosing part may push an internal atmosphere downward, thereby bringing the inert gas into contact with the substrate held by the substrate holding part.

In an aspect, the gas contact part may include a substrate holding part configured to hold the substrate, an enclosing part configured to surround the upper and lower sides and a portion of the lateral side of the substrate holding part, and a gas supply port configured to supply the inert gas into the enclosing part, and the gas contact part may be configured to supply the inert gas into the enclosing part to push an internal atmosphere downward to thereby bring the inert gas into contact with the substrate held by the substrate holding part.

With the above configuration, the inert gas supplied into the enclosing part may push the internal atmosphere toward the open lateral side inside, thereby bringing the inert gas into contact with the substrate held by the substrate holding part.

In an aspect, the inert gas may be a nitrogen gas.

With the above configuration, it is possible to reduce the exposure of the substrate to the ambient atmosphere more inexpensively and reliably.

In an aspect, the substrate processing apparatus may further include: a second gas contact part configured to bring the film into contact with the inert gas during a period after a process performed by a film-forming process part for forming a metal-containing resist film on the substrate and before the exposing process.

With the above configuration, the film before the exposing process is brought into contact with the inert gas by the second gas contact part. Therefore, it is possible to reduce the time during which the metal-containing resist film is in contact with the ambient atmosphere.

In an aspect, the substrate processing apparatus may further include: a transfer device configured to transfer the substrate; and a control part configured to control the transfer device, wherein the gas contact part may include an accommodation chamber provided in an interface block to accommodate the substrate after the exposing process, and a gas supply part configured to supply the gas into the accommodation chamber, and the control part may be configured to control the transfer device so as to unload the substrate from the accommodation chamber and load the substrate into the heat treatment part after the heat treatment part becomes ready to receive the substrate.

With the above configuration, the substrate may be brought into contact with the inert gas in the accommodation chamber until the heat treatment for the other substrate is completed. This may reduce the time during which the substrate is in contact with moisture and/or oxygen by waiting outside the unit.

In an aspect, the substrate processing apparatus may further include: a temperature adjustment unit configured to accommodate the substrate unloaded from the heat treatment part and perform a temperature adjustment process on the substrate, wherein the heat treatment part may include a hot plate configured to heat the substrate, the gas contact part may include a second accommodation chamber provided in the heat treatment part so as to accommodate the substrate subjected to a heat treatment on the hot plate, and a second gas supply part configured to supply the inert gas into the second accommodation chamber, and the control part may be configured to control the transfer device so as to unload the substrate from the second accommodation chamber and load the substrate into the temperature adjustment unit after the temperature adjustment unit becomes ready to receive the substrate.

With the above configuration, the substrate may be brought into contact with the inert gas in the second accommodation chamber of the heat treatment part until the temperature adjustment process for the other substrate is completed. This may reduce the time during which the substrate is in contact with moisture and/or oxygen by waiting outside the unit.

In an aspect, in the substrate processing apparatus, the gas contact part may further include a third gas supply part configured to supply the inert gas into the temperature adjustment unit, and the control part may be configured to control the transfer device so as to unload the substrate from the temperature adjustment unit and load the substrate into the developing process part after the developing process part becomes ready to receive the substrate.

With the above configuration, the substrate may be brought into contact with the inert gas in the temperature adjustment unit until the developing process for the other substrate is completed. This may reduce the time during which the substrate is in contact with moisture and/or oxygen by waiting outside the unit.

In an aspect, in the substrate processing apparatus, the heat treatment part may include a hot plate configured to heat the substrate, the gas contact part may include a second accommodation chamber of the heat treatment part so as to accommodate the substrate subjected to the heat treatment on the hot plate, and a second gas supply part configured to supply the inert gas into the second accommodation part, and the control part may be configured to control the transfer device so as to unload the substrate from the second accommodation chamber and load the substrate into the developing process part after the developing process part becomes ready to receive the substrate.

With the above configuration, the substrate may be brought into contact with the inert gas in the second accommodation chamber of the heat treatment part until the developing process for the other substrate is completed. This may reduce the time during which the substrate is in contact with moisture and/or oxygen by waiting outside the unit.

A substrate processing method according to an exemplary embodiment includes: forming a metal-containing resist film on a substrate; performing a heat treatment on the substrate having the film subjected to an exposing process; performing a developing process on the film of the substrate subjected to the heat treatment; and bringing the film into contact with an inert gas during a period after the exposing process and before the developing process.

According to the substrate processing method described above, the film is brought into contact with the inert gas in the gas contact part. Therefore, the time during which the metal-containing resist film is in contact with the ambient atmosphere may be shortened as compared with a case where the gas contact part is not provided.

In a non-transitory computer-readable recording medium that records a substrate processing program according to an exemplary embodiment, the substrate processing program causes a computer to execute a substrate processing which includes: forming a metal-containing resist film on a substrate; performing a heat treatment on the substrate having the film subjected to an exposing process; performing a developing process on the film of the substrate subjected to the heat treatment; and bringing the film into contact with an inert gas during a period after the exposing process and before the developing process.

According to the substrate processing program described above, the film is brought into contact with the inert gas in the gas contact part. Therefore, the time during which the metal-containing resist film is in contact with the ambient atmosphere may be shortened as compared with a case where the gas contact part is not provided.

### Exemplary Embodiment

Various exemplary embodiments will be described in detail below with reference to the drawings. In the respective drawings, the same or corresponding parts are designated by like reference numerals.

[Substrate Processing System]

The substrate processing system 1 is a system that forms a photosensitive film on a substrate, exposes the photosensitive film, and develops the photosensitive film. The workpiece W to be processed is, for example, a substrate, or a substrate on which a film, a circuit, or the like is formed by performing a predetermined process. The substrate is, for example, a silicon wafer. The workpiece W (substrate) may be circular. The workpiece W may be a glass substrate, a mask substrate, an FPD (Flat Panel Display), or the like. The photosensitive film is, for example, a resist film.

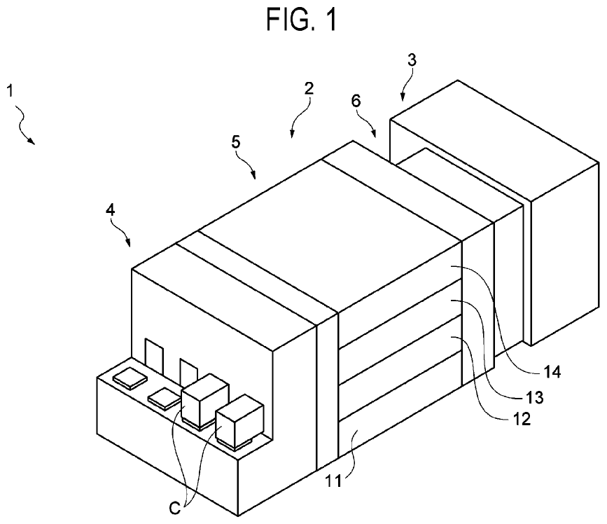

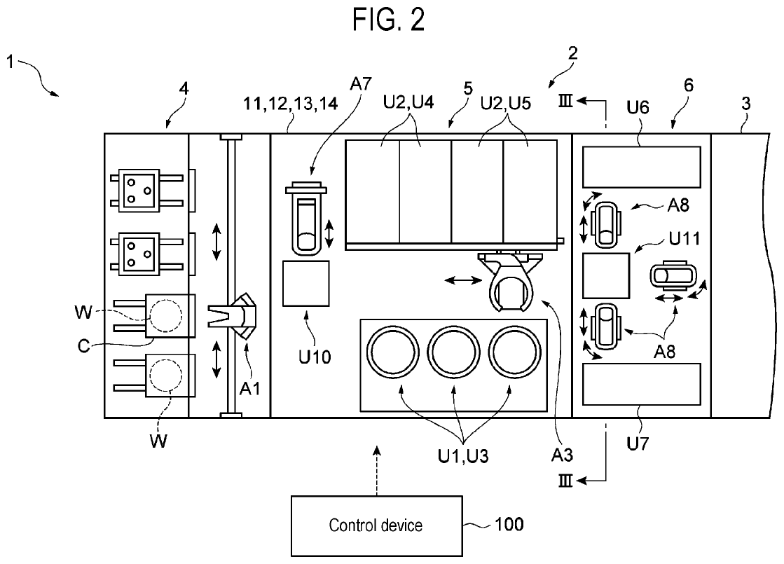

As illustrated in FIGS. 1 and 2, the substrate processing system 1 includes a coating developing apparatus 2 and an exposing apparatus 3. The exposing apparatus 3 is an exposing process apparatus for exposing a resist film (photosensitive film) formed on a workpiece W (substrate). For example, the internal space of the exposing apparatus 3 is kept in a substantially vacuum state. Specifically, the exposing apparatus 3 irradiates an exposure target portion of the resist film with an energy beam by a method such as liquid immersion exposure or the like. The energy beam is, for example, ionizing radiation or non-ionizing radiation. The ionizing radiation is radiation that has sufficient energy to ionize atoms or molecules. The ionizing radiation may be extreme ultraviolet (EUV), electron beams, ion beams, X-rays, α-rays, (β-rays, γ-rays, heavy particle beams, proton beams, or the like. The non-ionizing radiation is radiation that does not have sufficient energy to ionize atoms or molecules. The non-ionizing radiation may be g-rays, i-rays, KrF excimer laser, ArF excimer laser, F₂ excimer laser, or the like.

The coating developing apparatus 2 performs a process of forming a resist film by coating a resist (chemical solution) on the surface of the workpiece W before the exposing process is performed by the exposing apparatus 3, and performs a developing process on the resist film subjected to the exposing process. The substrate processing system 1 forms a metal-containing resist film by using a resist containing metal (hereinafter referred to as “metal-containing resist”). For example, the substrate processing system 1 may form the film by using a resist containing metal oxide.

### [Substrate Processing Apparatus]

A configuration of a coating developing apparatus 2 will be described below as an example of a substrate processing apparatus. As illustrated in FIGS. 1 and 2, the coating developing apparatus 2 includes a carrier block 4, a processing block 5, an interface block 6, and a control device 100.

The carrier block 4 loads the workpiece W into the coating developing apparatus 2 and unloads the workpiece W from the coating developing apparatus 2. For example, the carrier block 4 may support a plurality of carriers C for workpieces W, and includes a transfer device A1 having a transfer arm. The carrier C accommodates, for example, a plurality of circular workpieces W. The transfer device Al takes out the workpiece W from the carrier C, delivers the workpiece W to the processing block 5, receives the workpiece W from the processing block 5, and returns the workpiece W into the carrier C. The processing block 5 includes a plurality of processing modules 11, 12, 13 and 14.

The processing module 11 includes a coating unit U1, a heat treatment unit U2, and a transfer device A3 that transfers the workpiece W to these units. The processing module 11 forms a lower layer film on the surface of the workpiece W using the coating unit U1 and the heat treatment unit U2. The coating unit U1 coats the workpiece W with a processing liquid for forming the lower layer film. The heat treatment unit U2 performs various heat treatments associated with the formation of the lower layer film.

The processing module 12 includes a coating unit U1, a heat treatment unit U2, and a transfer device A3 that transfers the workpiece W to these units. The processing module 12 forms a film of metal-containing resist on the lower layer film using the coating unit U1 and the heat treatment unit U2. That is, the processing module 12 functions as a film-forming process part. The coating unit U1 coats the lower layer film with a metal-containing resist as a processing liquid for film formation. The heat treatment unit U2 performs various heat treatments associated with film formation. As a result, a film of metal-containing resist is formed on the surface of the workpiece W.

The processing module 13 includes a coating unit U1, a heat treatment unit U2, and a transfer device A3 that transfers the workpiece W to these units. The processing module 13 forms an upper layer film on the resist film using the coating unit U1 and the heat treatment unit U2. The coating unit U1 coats the resist film with a liquid for forming an upper layer film. The heat treatment unit U2 performs various heat treatments associated with the formation of the upper layer film.

The processing module 14 includes a developing unit U3 (developing process part), a heat treatment unit U4 (heat treatment part), a temperature adjustment unit U5 (inert gas contact part), and a transfer device A3 that transfers the workpiece W to these units. The processing module 14 performs a developing process on the film subjected to the exposing process and a heat treatment associated with the developing process using the developing unit U3 and the heat treatment unit U4. As a result, a resist pattern made of a metal-containing resist is formed on the surface of the workpiece W. The developing unit U3 performs on the metal-containing resist film by coating a developing liquid on the exposed surface of the workpiece W and then rinsing the developing liquid with a rinsing liquid. Alternatively, the developing unit U3 may perform a developing process on the metal-containing resist film by dry development using a developing gas. For example, when the metal-containing resist is of a positive type, the workpiece W may be exposed to a developing gas to selectively remove the region of the metal-containing resist of the workpiece W that has been exposed to EUV. If the metal-containing resist is of a negative type, the workpiece W may be exposed to a developing gas to selectively remove the region of the metal-containing resist of the workpiece W other than the region that has been exposed to EUV. The heat treatment unit U4 performs various heat treatments associated with the developing process. Specific examples of the heat treatment include a heating treatment before developing process (PEB: Post-Exposure Bake), a heating treatment after developing process (PB: Post Bake), and the like. The developing unit U3 performs a developing process on the workpiece W subjected to the heating treatment (PEB) using the heat treatment unit U4. Further, the temperature adjustment unit U5 has a function of adjusting the temperature of the workpiece W subjected to the heating treatment (PEB) in the heat treatment unit U4 before the developing process is performed by the developing unit U3.

Hereinafter, unless otherwise specified, the heating treatment in the heat treatment unit U4 is referred to as “heating treatment before developing process (PEB)”. In addition, the film of metal-containing resist is simply referred to as a “film”.

A shelf unit U10 is provided on the carrier block 4 side in the processing block 5. The shelf unit U10 is partitioned into a plurality of vertically aligned cells. A transfer device A7 including an elevating arm is provided in the vicinity of the shelf unit U10. The transfer device A7 raises and lowers the workpiece W between the cells of the shelf unit U10.

The interface block 6 transfers the workpiece W to and from the exposing apparatus 3. The interface block 6 is provided with a shelf unit U11. The shelf unit U11 is partitioned into a plurality of vertically aligned cells. The transfer device A3 delivers the workpiece W between the respective units in the processing block 5 and the cells of the shelf unit U11.

Further, the interface block 6 includes a transfer device A8 including a delivery arm and is connected to the exposing apparatus 3. The interface block 6 is provided with a gas supply unit U6 (inert gas contact part). The gas supply unit U6 has a function of bringing the film formed on the surface of the workpiece W into contact with an inert gas. The configuration of the gas supply unit U6 will be described later. Further, the interface block 6 is provided with a cleaning unit U7 for cleaning the front surface or the back surface of the workpiece W in addition to the gas supply unit U6 described above.

The transfer device A8 in the interface block 6 delivers the workpiece W placed on the shelf unit U11 to the exposing apparatus 3. The transfer device A8 receives the workpiece W from the exposing apparatus 3 and returns the workpiece W to the shelf unit U11 via the gas supply unit U6. Further, the transfer device A8 also delivers the workpiece W between the shelf unit U11 and the cleaning unit U7. Therefore, a plurality of transfer devices A8 are arranged in the interface block 6. In the example illustrated in FIGS. 1 to 3, three transfer devices A8 are arranged in the interface block 6.

The control device 100 controls the coating developing apparatus 2 so as to execute a coating developing process, for example, in the following procedure. First, the control device 100 controls the transfer device A1 so as to transfer the workpiece W in the carrier C to the shelf unit U10, and controls the transfer device A7 so as to arrange the workpiece W in the cell for the processing module 11.

Subsequently, the control device 100 controls the transfer device A3 so as to transfer the workpiece W on the shelf unit U10 to the coating unit U1 and the heat treatment unit U2 in the processing module 11. Further, the control device 100 controls the coating unit U1 and the heat treatment unit U2 so as to form a lower layer film on the surface of the workpiece W. Thereafter, the control device 100 controls the transfer device A3 so as to return the workpiece W on which the lower layer film is formed to the shelf unit U10, and controls the transfer device A7 so as to arrange the workpiece W in the cell for the processing module 12.

Subsequently, the control device 100 controls the transfer device A3 so as to transfer the workpiece W on the shelf unit U10 to the coating unit U1 and the heat treatment unit U2 in the processing module 12. Further, the control device 100 controls the coating unit U1 and the heat treatment unit U2 so as to form a metal-containing resist film on the lower layer film of the workpiece W. Thereafter, the control device 100 controls the transfer device A3 so as to return the workpiece W to the shelf unit U10, and controls the transfer device A7 so as to arrange the workpiece W in the cell for the processing module 13.

Subsequently, the control device 100 controls the transfer device A3 so as to transfer the workpiece W on the shelf unit U10 to each unit in the processing module 13. Further, the control device 100 controls the coating unit U1 and the heat treatment unit U2 so as to form an upper layer film on the film of the workpiece W. Thereafter, the control device 100 controls the transfer device A3 so as to transfer the workpiece W to the shelf unit U11.

Subsequently, the control device 100 controls the transfer device A8 so as to send out the workpiece W on the shelf unit U11 to the exposing apparatus 3. Thereafter, the control device 100 controls the transfer device A8 so as to receive the workpiece W subjected to the exposing process from the exposing apparatus 3 and load the workpiece W into the gas supply unit U6. Then, the control device 100 controls the transfer device A8 so as to arrange the workpiece W of the gas supply unit U6 in the cell of the shelf unit U11 for the processing module 14.

Subsequently, the control device 100 controls the transfer device A3 so as to transfer the workpiece W on the shelf unit U11 to the heat treatment unit U4 in the processing module 14. Then, the control device 100 controls the heat treatment unit U4 so as to perform a heat treatment on the film of the workpiece W. Subsequently, the control device 100 adjusts the temperature of the heated workpiece W using the temperature adjustment unit U5. Subsequently, the control device 100 controls the developing unit U3 and the heat treatment unit U4 so as to perform a developing process and a heating treatment after developing process on the film of the workpiece W subjected to the temperature adjustment. Thereafter, the control device 100 controls the transfer device A3 so as to return the workpiece W to the shelf unit U10, and controls the transfer devices A7 and A1 so as to return the workpiece W into the carrier C. Thus, the coating developing process is completed.

A specific configuration of the substrate processing apparatus is not limited to the configuration of the coating developing apparatus 2 illustrated above. The substrate processing apparatus may be any type of apparatus as long as it includes a unit configured to perform a film-forming process for forming a metal-containing resist film, a heat treatment unit configured to perform a heating treatment on the film subjected to an exposing process, a developing unit configured to perform developing process on the film, and a control device capable of controlling these units. The gas supply unit U6 may be provided in the carrier block 4 or the processing modules 11, 12, 13 and 14.

In the coating developing process performed in the substrate processing apparatus described above, the reaction of the metal-containing resist occurs even in a period after the exposing process and before the start of the developing process. Therefore, the length of the post-exposure delay time (PED time) from the end of the exposing process performed in the exposing apparatus 3 to the post-exposure heat treatment (PEB) for the workpiece W in the heat treatment unit U4 of the processing module 14 may possibly affect the line width (CD). In addition, the length of the post-heating delay time (PPD time) from the post-exposure heat treatment (PEB) to the start of the developing process for the workpiece W in the developing unit U3 may also possibly affect the line width (CD) on the surface of the workpiece W. Specifically, when the post-exposure delay time (PED time) and/or the post-heating delay time (PPD time) increases, the line width of the film formed on the workpiece W tends to increase. That is, when the total time of the post-exposure delay time (PED time and post-heating delay time (PPD time)) varies for each workpiece W, the line width variation for each workpiece W increases. Presumably, this is because the metal-containing resist reacts with moisture and/or oxygen in the ambient atmosphere during the above-described delay time. In addition, just like oxygen, carbon dioxide, which is a gas containing oxygen atoms, may also affect the line width (CD) of the metal-containing resist. That is, the line width (CD) of metal-containing resists is susceptible to being affected by the ambient atmosphere containing moisture, oxygen, and/or carbon dioxide. The ambient atmosphere may refer to an atmosphere filled with air.

However, since the transfer devices described above are controlled asynchronously and independently of each other, the delay time inevitably varies for each workpiece W depending on the transfer circumstances. Therefore, in order to ensure line width uniformity in the workpiece W, it is necessary to reduce the contact between the surface of the workpiece W and moisture during the delay time described above. As the configuration for this purpose, the substrate processing apparatus includes a configuration for allowing the above-described delay time to elapse while avoiding the contact between the surface of the workpiece W and moisture and/or oxygen in the route until the workpiece W unloaded from the exposing apparatus 3 is loaded into the developing unit U3. Specifically, in the gas supply unit U6, the heat treatment unit U4, and the temperature adjustment unit U5, the above-described delay time is allowed to elapse while avoiding the contact between the metal-containing resist on the surface of the workpiece W and moisture and/or oxygen. A specific configuration for that purpose will now be described.

### (Gas Supply Unit)

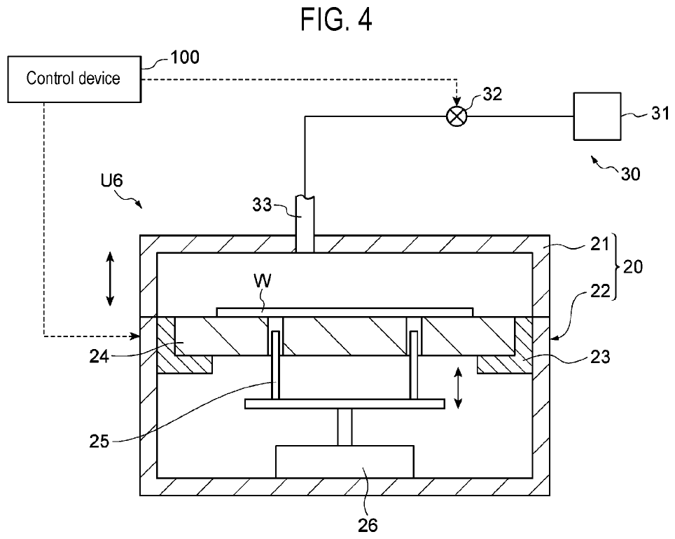

First, the configuration of the gas supply unit U6 will be described. As illustrated in FIG. 4, the gas supply unit U6 includes a chamber 20, a plurality of support pins 25, and a gas supply part 30.

The chamber 20 forms a heat treatment space for performing a gas treatment. The chamber 20 includes an upper chamber 21 and a lower chamber 22. The upper chamber 21 is connected to a driving part (not illustrated) and is moved vertically with respect to the lower chamber 22. The upper chamber 21 includes a top plate facing the workpiece W arranged in the chamber 20 and a side wall surrounding the workpiece W. The lower chamber 22 includes a holding part 23 and supports a holding plate 24 that holds the workpiece W.

The support pins 25 are pins that support the workpiece W from below. The support pins 25 extend vertically through the holding plate 24. The support pins 25 may be arranged at regular intervals in the circumferential direction around the center of the holding plate 24. The driving part 26 raises and lowers the support pins 25 according to the instructions from the control device 100. The driving part 26 is, for example, an elevating actuator.

The gas supply part 30 is configured to supply a gas into the chamber 20 (heat treatment space). The gas supplied by the gas supply part 30 is an inert gas. As an example, the gas supply part 30 supplies a nitrogen (N₂) gas into the chamber 20. However, the inert gas may be an argon (Ar) gas instead of the nitrogen gas, or other inert gases. The inert gas has low reactivity with the metal-containing resist and has a property of hardly affecting the line width (CD) of the metal-containing resist as compared with the air containing moisture, oxygen, carbon dioxide, and the like. The inert gas may be a gas that does not contain a gas that may affect the line width (CD) of a metal-containing resist. The inert gas may be a gas that does not contain oxygen. The inert gas may be a gas that does not contain carbon dioxide. The gas supply part 30 includes a gas source 31, a valve 32 and a pipe 33. The gas source 31 functions as a source of a gas. The valve 32 is switched between an open state and a closed state according to the instructions from the control device 100. The gas source 31 sends a gas into the chamber 20 (heat treatment space) through the pipe 33 when the valve 32 is open.

In the gas supply unit U6 described above, the gas is supplied from the gas supply part 30 while the chamber 20 is closed when holding the workpiece W. As a result, since the inside of the chamber 20 becomes an inert gas atmosphere, it is possible to suppress the contact between the surface of the workpiece W and moisture.

### (Heat Treatment Unit)

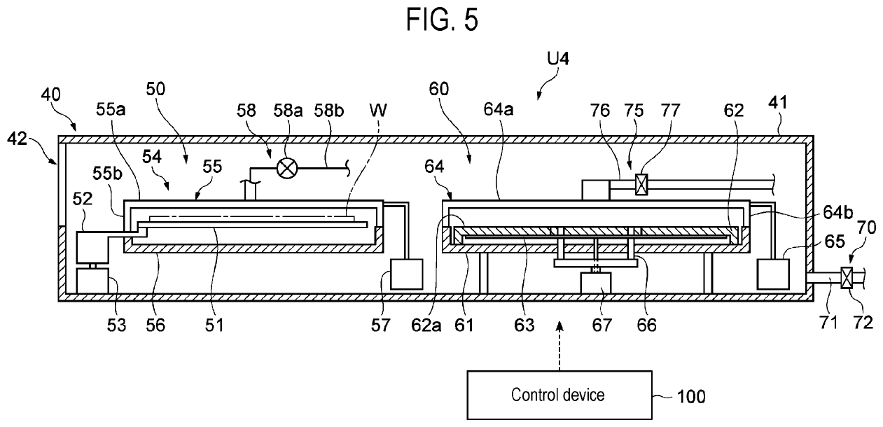

Next, a configuration of the heat treatment unit U4 will be described. As illustrated in FIG. 5, the heat treatment unit U4 includes a processing chamber 40, a temperature adjustment part 50, and a heating part 60.

The processing chamber 40 accommodates a workpiece W to be heat-treated. The processing chamber 40 includes a housing 41. The housing 41 is a processing container that accommodates the temperature adjustment part 50 and the heating part 60. A loading port 42 for loading the workpiece W is formed in the side wall of the housing 41.

The temperature adjustment part 50 is a mechanism that adjusts the temperature of the workpiece W in the processing chamber 40 to a predetermined temperature. The adjustment of the temperature of the workpiece W in the temperature adjustment part 50 may be a part of the heat treatment performed in the heat treatment unit U4. The temperature adjustment unit 50 delivers the workpiece W to and from the external transfer device A3. The temperature adjustment part 50 includes a temperature adjustment plate 51, a connection bracket 52, a driving mechanism 53, a chamber 54 and a gas supply part 58.

The temperature adjustment plate 51 is a plate for adjusting the temperature of the workpiece W placed thereon. Specifically, the temperature adjustment plate 51 is a cool plate on which the workpiece W heated by the heating part 60 is placed and which cools the workpiece W to a predetermined temperature. For example, the temperature adjustment plate 51 may be formed in a substantially disk shape. The temperature adjustment plate 51 may be made of metal with high thermal conductivity, such as aluminum, silver, or copper. A cooling channel (not illustrated) for circulating cooling water or cooling gas is formed inside the temperature adjustment plate 51.

The connection bracket 52 is connected to the temperature adjustment plate 51. The driving mechanism 53 is operated based on the instructions from the control device 100 to move the connection bracket 52. The connection bracket 52 is moved inside the housing 41 by the driving mechanism 53. Specifically, the connection bracket 52 is moved along a guide rail (not illustrated) extending between the loading port 42 of the housing 41 and the vicinity of the heating part 60 so that the temperature adjustment plate 51 may be moved between the loading port 42 and the heating part 60.

The chamber 54 is configured to surround the placement surface of the temperature adjustment plate 51, on which the workpiece W is placed, when the temperature adjustment plate 51 is moved to a predetermined position. The chamber 54 is composed of an upper chamber 55 and a lower chamber 56. The upper chamber 55 includes a top plate portion 55a and a leg portion 55b. The top plate portion 55a is configured as a disk that faces the placement surface of the temperature adjustment plate 51 in the vertical direction. The leg portion 55b is configured to extend downward from the outer edge of the top plate portion 55a. The lower chamber 56 is arranged at a position opposed to the upper chamber 55 in the vertical direction. The elevating mechanism 57 is a mechanism for elevating the upper chamber 55 according to the instructions from the control device 100. When the upper chamber 55 is raised by the elevating mechanism 57, the space for heat-treating the workpiece W is opened, and when the upper chamber 55 is lowered, the space for heat-treating the workpiece W is substantially closed. The chamber 54 does not have to be completely closed.

The gas supply part 58 (second gas supply part) is configured to supply a gas into the chamber 54 (heat treatment space). The gas supplied by the gas supply part 58 is an inert gas. As an example, the gas supply part 58 supplies a nitrogen (N₂) gas into the chamber 54. However, the inert gas may be an argon (Ar) gas instead of the nitrogen gas, or other inert gases. The gas supply part 58 includes a gas source (not illustrated), a valve 58a, and a pipe 58b. The gas source functions as a source of a gas. The valve 58a is switched between an open state and a closed state according to the instructions from the control device 100. The gas source sends a gas into the chamber 54 (heat treatment space) through the pipe 58b when the valve 58a is open.

The heating part 60 is a mechanism that heats the workpiece W in the processing chamber 40. The heating part 60 includes a support base 61, a hot plate 62, a heater 63, a chamber 64 (lid), an elevating mechanism 65, support pins 66, and an elevating mechanism 67.

The support base 61 has a cylindrical shape with a recess formed at the central portion thereof, and supports the hot plate 62. The hot plate 62 is, for example, substantially disc-shaped and is accommodated in the recess of the support base 61. The hot plate 62 supports the workpiece W by placing a processing target workpiece W on the placement surface 62a of the hot plate 62. In this state, the hot plate 62 heats the workpiece W placed thereon. A heater 63 for heating the hot plate 62 may be provided on the lower surface of the hot plate 62. The heater 63 may be embedded within the hot plate 62.

The chamber 64 is configured to surround the placement surface 62a of the workpiece W on the hot plate 62. The chamber 64 includes a top plate portion 64a and a leg portion 64b. The top plate portion 64a is configured in a disk shape and arranged to face the placement surface 62a of the hot plate 62 in the vertical direction. The leg portion 64b is configured to extend downward from the outer edge of the top plate portion 64a. The elevating mechanism 65 is a mechanism that raises and lowers the chamber 64 according to the instructions from the control device 100. By raising the chamber 44 by the elevating mechanism 65, the space for heat-treating the workpiece W is opened, and by lowering the chamber 64, the space for heat-treating the workpiece W is closed.

The support pins 66 are pins that extend vertically so as to penetrate the support base 61 and the hot plate 62 and support the workpiece W from below. The support pins 66 arranges the workpiece W at a predetermined position by moving up and down. The support pins 66 deliver the workpiece W to and from the temperature adjustment plate 51 that transfers the workpiece W. The support pins 66 may be composed of, for example, three pins arranged at equal intervals in the circumferential direction. The elevating mechanism 67 is a mechanism for raising and lowering the support pins 46 according to the instructions from the control device 100. The elevating mechanism 67 is configured to move the workpiece W closer to the hot plate 62 and raise and lower the support pins 66 that support the workpiece W so that the workpiece W is placed on the hot plate 62.

The exhaust part 70 exhausts a gas from the processing chamber 40. For example, the exhaust part 70 exhausts a gas from the processing chamber 40 to the outside of the heat treatment unit U4 (coating developing apparatus 2). The exhaust part 70 includes an exhaust duct 71 and an opening/closing part 72. The exhaust duct 71 connects the space in the processing chamber 40 (the space defined by the housing 41) and the discharge destination. The opening/closing part 72 is provided on the flow path of the exhaust duct 71 and switches the flow path of the exhaust duct 71 between an open state and a blocked state according to the instructions from the control device 100.

The exhaust part 75 exhausts a gas from the space within the chamber 64 defined by the support base 61 and the chamber 64. The space in the chamber 64 is included in the space inside the processing chamber 40. For example, the exhaust part 75 exhausts a gas from the chamber 64 to the outside of the heat treatment unit U4 (coating developing apparatus 2). The exhaust part 75 includes an exhaust duct 76 and an opening/closing part 77. The exhaust duct 76 connects the space in the chamber 64 and the exhaust destination. The exhaust duct 76 is connected to, for example, the top plate portion 64a of the chamber 64. The opening/closing part 77 is provided on the flow path of the exhaust duct 76 and switches the flow path of the exhaust duct 76 between an open state and a blocked state according to the instructions from the control device 100.

The total exhaust amount of the gas discharged from the exhaust part 70 and the exhaust part 75 may be changed by controlling the opening/closing states of the opening/closing parts 72 and 77.

In the heat treatment unit U4 described above, a gas is supplied from the gas supply part 58 while the chamber 54 is closed when holding the workpiece W on the temperature adjustment plate 51. As a result, the inside of the chamber 54 becomes an inert gas atmosphere, thereby suppressing the contact between the surface of the workpiece W and moisture.

### (Temperature Adjustment Unit)

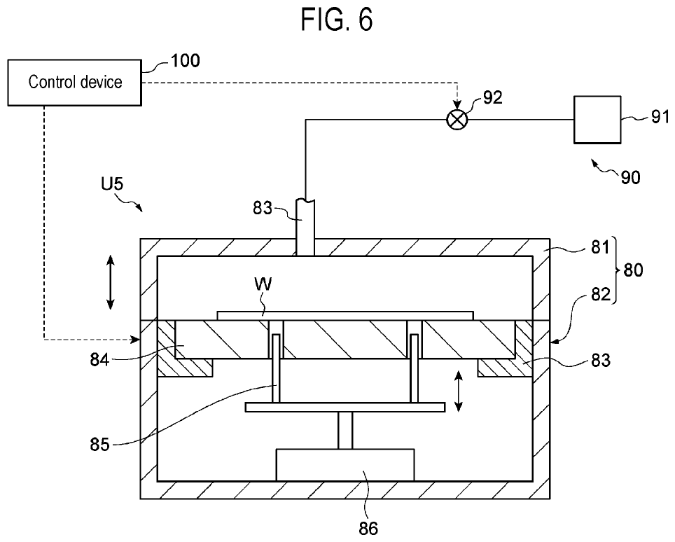

Next, a configuration of the temperature adjustment unit U5 will be described. As illustrated in FIG. 6, the temperature adjustment unit U5 includes a temperature adjustment plate 84, a chamber 80, a plurality of support pins 85, and a gas supply part 90.

The temperature adjustment plate 84 supports the workpiece W whose temperature is to be adjusted, and adjusts the temperature of the supported workpiece W to a predetermined temperature. As an example, the temperature adjustment plate 84 is formed in a substantially disk shape. The temperature adjustment plate 84 may be made of metal with high thermal conductivity, such as aluminum, silver, or copper. The temperature adjustment plate 84 may be cooled by a refrigerant (not illustrated) or the like.

The chamber 80 forms a processing space for performing a temperature adjustment process. The chamber 80 includes an upper chamber 81 and a lower chamber 82. The upper chamber 81 is connected to a driving part (not illustrated) and is moved vertically with respect to the lower chamber 82. The upper chamber 81 includes a top plate facing the workpiece W on the temperature adjustment plate 84 and a side wall surrounding the workpiece W on the temperature adjustment plate 84. The lower chamber 82 includes a holding part 83 and holds the temperature adjustment plate 84.

The support pins 85 are pins that support the workpiece W from below. The support pins 85 extend vertically through the temperature adjustment plate 84. A plurality of support pins 85 may be arranged at regular intervals in the circumferential direction around the center of the temperature adjustment plate 84. The driving part 86 raises and lowers the support pins 85 according to the instructions from the control device 100. The driving part 86 is, for example, an elevating actuator.

The gas supply part 90 (third gas supply part) is configured to supply a gas into the chamber 80 (heat treatment space). For example, the gas supply part 90 supplies an inert gas as the gas. For example, the gas supply part 90 supplies a nitrogen gas into the chamber 80. The gas supply part 90 includes a gas source 91, a valve 92, and a pipe 93. The gas source 91 functions as a source of a gas. The valve 92 is switched between an open state and a closed state according to the instructions from the control device 100. The gas source 91 sends a gas into the chamber 80 through the pipe 93 when the valve 92 is open.

In the temperature adjustment unit U5 described above, the gas is supplied from the gas supply part 90 while the chamber 80 is closed when holding the workpiece W. As a result, the inside of the chamber 80 becomes an inert gas atmosphere, thereby suppressing the contact between the surface of the workpiece W and moisture.

### (Control Device)

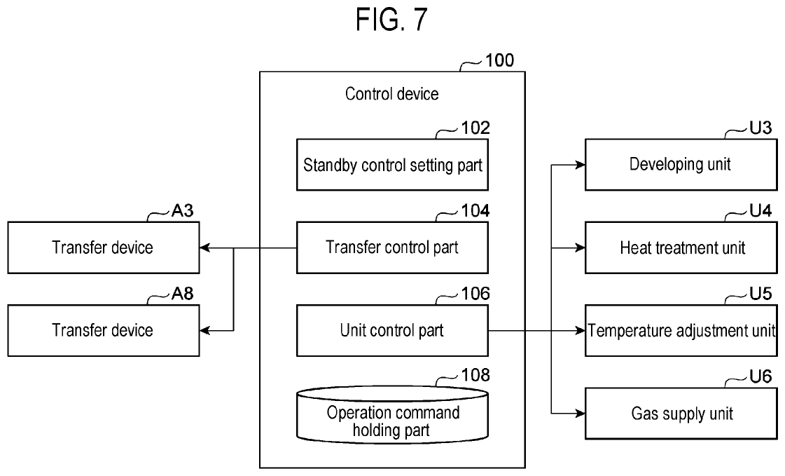

The control device 100 illustrated in FIGS. 2 and 7 controls each component included in the coating developing apparatus 2. The control device 100 is configured to execute: forming a metal-containing resist film on the workpiece W; performing a heat treatment on the workpiece W having the film subjected to an exposing process; performing a developing process on the film of the workpiece W subjected to the heat treatment; and bringing the film into contact with an inert gas during a period after the exposing process and before the developing process.

As illustrated in FIG. 7, the control device 100 includes a standby control setting part 102, a transfer control part 104, a unit control part 106, and an operation command holding part 108 as functional components (hereinafter referred to as “functional modules”). The operation command holding part 108 may contain, for example, a processing schedule including a transfer plan for each of the plurality of workpieces W.

The standby control setting part 102 is configured to calculate a reference transfer time for each workpiece W and set the time for bringing each workpiece W into contact with the inert gas from the reference transfer time. For example, the reference transfer time is a fixed target value for the time it takes for the processing module 12 to transfer one workpiece W unloaded from the exposing apparatus 3 to the developing unit U3. The standby control setting part 102 acquires the reference transfer time based on the transfer plan held in the operation command holding part 108.

The reference transfer time also includes the time during which the workpiece W is processed in the heat treatment unit U4 or the temperature adjustment unit U5 of the processing module 14. Since the predetermined process to be performed for the workpiece W in each unit is determined in advance, the remaining time of the reference transfer time is the standby time during which the workpiece W is not subjected to the predetermined process.

In other words, the standby time includes the time during which any transfer device supports and transfers the workpiece W and the time during which the workpiece W is not transferred by the transfer device. The standby control setting part 102 determines in which unit each workpiece W is to be kept on standby. As described above, the standby time is set so that each workpiece W is brought into contact with the inert gas as much as possible. More specific standby time and control content are more specifically determined so that the workpiece W is kept on standby in one of the gas supply unit U6, the temperature adjustment part 50 of the heat treatment unit U4, and the temperature adjustment unit U5.

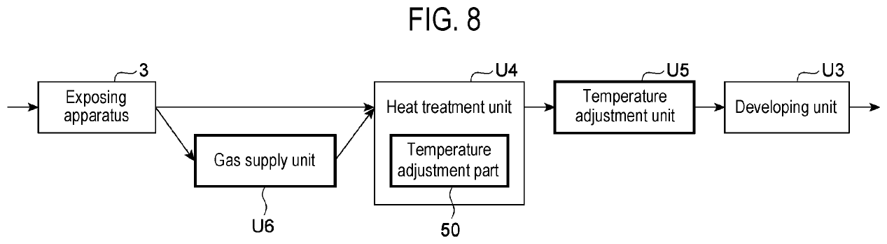

As illustrated in FIG. 8, the workpiece W unloaded from the exposing apparatus 3 is loaded into the developing unit U3 through at least the heat treatment unit U4 and the temperature adjusting unit U5. Further, some of the workpieces W pass through the gas supply part U6 before reaching the heat treatment unit U4. On this path, the gas supply unit U6, the temperature adjustment part 50 of the heat treatment unit U4, and the temperature adjustment unit U5 have spaces in which the inert gas is supplied to the surface of the workpiece W. Therefore, the standby control setting part 102 determines the standby space and the standby time for each workpiece W.

The coating developing apparatus 2 has different numbers of gas supply units U6, heat treatment units U4, and temperature adjustment units U5. Therefore, a different moving path is set for each workpiece W. Further, since a plurality of workpieces W are processed simultaneously in the apparatus, the number of workpieces W to be processed in the coating developing apparatus 2 decreases when all the workpieces W are kept on standby at the same standby position. Therefore, the standby control setting part 102 determines the standby position and standby time of each workpiece W while considering the processing efficiency of the workpiece W. Depending on the workpiece W, the workpiece W may not pass through the gas supply unit U6. Whether or not to pass through the gas supply unit U6 is also determined by the standby control setting part 102.

The transfer control part 104 controls the transfer device A3 and the transfer device A8 so as to transfer the workpiece W. The transfer control part 104 controls the movement timing and the like of each workpiece W based on the standby position and standby time set by the standby control setting part 102. The transfer control part 104 controls the transfer devices A3 and A8 so that each workpiece W is loaded into a predetermined unit during the adjusted accommodation standby time.

The unit control part 106 controls each of the units (e.g., the developing unit U3, the heat treatment unit U4, the temperature adjustment unit U5, and the gas supply unit U6) into which the workpiece W is loaded based on the operation command holding part 108.

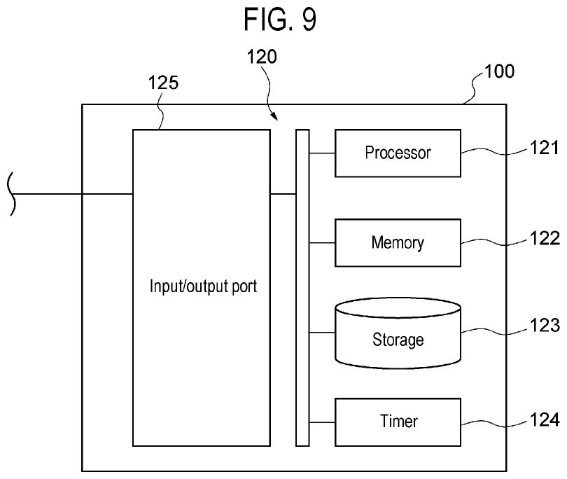

The control device 100 is composed of one or more control computers. For example, control device 100 includes a circuit 120 illustrated in FIG. 9. The circuit 120 includes one or more processors 121, a memory 122, a storage 123, a timer 124, and an input/output port 125. The storage 123 includes a computer-readable storage medium such as a hard disk or the like. The storage medium stores a program for causing the control device 100 to execute a substrate processing procedure, which will be described later. The storage medium may be a removable medium such as a non-volatile semiconductor memory, a magnetic disk, an optical disk, or the like. The memory 122 temporarily stores the program loaded from the storage medium of the storage 123 and the calculation result obtained by the processor 121. The processor 121 cooperates with the memory 122 to execute the program, thereby providing each functional module described above. The input/output port 125 inputs/outputs electric signals to/from the transfer devices A3 and A8 and the respective units in accordance with the instructions from the processor 121. The timer 124 measures the elapsed time by, for example, counting reference pulses of a constant cycle.

The hardware configuration of the control device 100 is not necessarily limited to providing each functional module by a program. For example, each functional module of the control device 100 may be composed of a dedicated logic circuit or an ASIC (Application Specific Integrated Circuit) integrating the dedicated logic circuit.

### [Substrate Processing Procedure]

Next, as an example of the substrate processing method, a substrate processing procedure executed in the coating developing apparatus 2 will be described. This substrate processing procedure includes: forming a film (metal-containing resist film) on a workpiece W; performing a heat treatment on the workpiece W having the film subjected to an exposing process; and performing a developing process on the film of the workpiece W subjected to the heat treatment. The substrate processing procedure further includes: bringing the surface of the workpiece W into contact with an inert gas before developing the film subjected to exposure.

Further, in the following procedure, it is assumed that the standby location and standby time of each workpiece W are determined by the standby control setting part 102 of the control device 100.

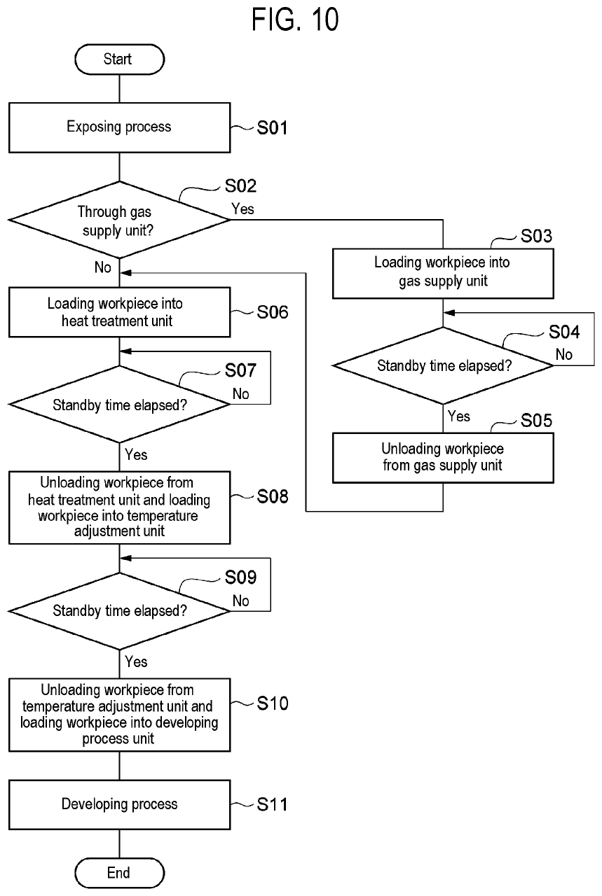

FIG. 10 is a flowchart illustrating the procedure for processing the workpiece W after the exposing process. First, the control device 100 executes step S01. In step S01, the unit control part 106 executes an exposing process on the workpiece W based on the transfer plan stored in the operation command holding part 108.

Subsequently, the control device 100 executes step S02. In step S02, the transfer control part 104 determines whether or not to transfer the workpiece W subjected to the exposing process via the gas supply unit U6 based on the transfer plan stored in the operation command holding part 108 and the standby position and standby time set by the standby control setting part 102. As a result of the determination, when it is determined that the workpiece W passes through the gas supply part U6 (YES in S02), the control device 100 executes step S03. In step S03, the transfer control part 104 controls the transfer device A8 so as to load the workpiece W into the gas supply unit U6. Further, in step S03, the unit control part 106 may control the gas supply unit U6 to open and close the chamber 20 when loading the workpiece W and start supplying a gas from the gas supply part 30.

Subsequently, control device 100 executes step S04. In step S04, the transfer control part 104 determines whether a predetermined standby time has elapsed in the gas supply unit U6 based on the standby position and standby time set by the standby control setting part 102. If the predetermined standby time has not elapsed (NO in S04), the workpiece W is kept on standby in the gas supply unit U6 until the predetermined standby time has elapsed. On the other hand, when the predetermined standby time is determined to have elapsed (YES in S04), the control device 100 executes step S05. In step S05, the transfer control part 104 controls the transfer device A8 so as to unload the workpiece W from the gas supply unit U6.

When it is determined in step S02 that the workpiece W does not pass through the gas supply unit U6 (NO in S02), or after step S05 is executed, the control device 100 executes step S06. In step S06, the transfer control part 104 controls the transfer device A8 so as to load the workpiece W into the heat treatment unit U4. Furthermore, in step S06, the unit control part 106 controls the heat treatment unit U4 to heat the workpiece W in the heating part 60 in the processing chamber 40 for a predetermined time, and then moves the workpiece W to the temperature adjustment part 50.

Subsequently, the control device 100 executes step S07. In step S07, the transfer control part 104 determines whether a predetermined standby time has elapsed in the heat treatment unit U4 based on the standby position and standby time set by the standby control setting part 102. When the predetermined standby time is determined to have not elapsed (NO in S07), the workpiece W is kept on standby in the temperature adjustment part 50 until the predetermined standby time has elapsed. In a state in which the standby control setting part 102 performs setting so that the workpiece W is not kept on standby in the temperature adjustment part 50 of the heat treatment unit U4, it is determined that the predetermined standby time has elapsed (YES in S07), and the process proceeds to the subsequent process.

When the predetermined standby time is determined to have elapsed (YES in S07), the control device 100 executes step S08. In step S08, the transfer control part 104 controls the transfer device A3 so as to unload the workpiece W from the heat treatment unit U4 and then load the workpiece W into the temperature adjustment unit U5. Further, in step S08, the unit control part 106 may control the temperature adjustment unit U5 to open and close the chamber 80 when loading the workpiece W, and may cause the gas supply part 90 to start supplying a gas.

Subsequently, the control device 100 executes step S09. In step S09, the transfer control part 104 determines whether a predetermined standby time has elapsed in the temperature adjustment unit U5 based on the standby position and standby time set by the standby control setting part 102. When the predetermined standby time is determined to have not passed (NO in S09), the workpiece W is kept on standby in the temperature adjustment unit U5 until the predetermined standby time has elapsed. On the other hand, when the predetermined standby time is determined to have elapsed (YES in S09), the control device 100 executes step S10. In step S10, the transfer control part 104 controls the transfer device A3 so as to unload the workpiece W from the temperature adjustment unit U5 and then load the workpiece W into the developing unit U3. Thereafter, the control device 100 executes step S11. In step S11, the unit control part 106 controls the developing unit U3 to perform a developing process on the workpiece W. Thus, the developing process of the workpiece W is completed.

### Effects of the Embodiment

The coating developing apparatus 2 according to the present embodiment described above includes a coating unit U1 as a film-forming process part configured to form a metal-containing resist film, a heat treatment unit U4 as a heat treatment part configured to perform a heat treatment on the workpiece W having the film subjected to an exposing process, a developing unit U3 configured to perform a developing process on the film of the workpiece W subjected to the heat treatment, and a gas contact part (e.g., a gas supply unit U6, a heat treatment unit U4, and a temperature adjustment unit U5) configured to bring the film into contact with an inert gas during a period after the exposing process and before the developing process.

In the coating developing apparatus 2 described above, the film is in contact with the inert gas in the gas contact part. Therefore, it is possible to shorten the time during which the metal-containing resist film is in contact with the ambient atmosphere as compared with the case where the gas contact part is not provided. As described in the above embodiment, in the gas supply unit U6, the heat treatment unit U4, and the temperature adjustment unit U5, which function as the gas contact part, it is possible to avoid the contact of the metal-containing resist on the surface of the workpiece W with moisture and/or oxygen. Therefore, it is possible to shorten the contact time with the ambient atmosphere.

The gas contact part may be a gas supply unit U6 as a gas processing unit configured to temporarily place the workpiece W in a predetermined housing and including a gas supply part for supplying a gas into the housing. Further, the gas supply unit U6 may be provided in the interface block 6. With such a configuration, the film may be brought into contact with the inert gas by transfer the workpiece W into the gas supply unit U6. Further, in a case in which the gas supply unit U6 is provided in the interface block 6, the workpiece W may be transferred to the gas supply unit U6 while the workpiece W is being transferred to and from the exposing apparatus 3. Therefore, the transfer time to the gas supply unit U6 may also be shortened, and the time during which the workpiece W is exposed to the ambient atmosphere may be reduced.

The heat treatment unit U4 as a heat treatment part may include the hot plate 62 that heats the workpiece W and the temperature adjustment plate 51 that holds the workpiece W subjected to the heat treatment on the hot plate 62. At this time, the gas contact part may include the gas supply part 58 as a second gas supply part that supplies the inert gas so that the temperature adjustment plate 51 of the heat treatment unit U4 and the film of the workpiece W on the temperature adjustment plate 51 are in contact with the inert gas. In the heat treatment unit U4, the film of the workpiece W held by the temperature adjustment plate 51 after the heat treatment may also be brought into contact with the inert gas.

The gas contact part may further include the chamber 54 that surrounds the temperature adjustment plate 51 so that the inert gas supplied from the gas supply part 58 as the second gas supply part contacts the film. By surrounding the temperature adjustment plate 51 with the chamber 54, the inert gas supplied from the gas supply part 58 may be easily brought into contact with the film.

The gas contact part may be the temperature adjustment unit U5 that temporarily holds the workpiece W unloaded from the heat treatment unit U4 before it is loaded into the developing unit U3 as a developing process part. At this time, the temperature adjustment unit U5 may include the gas supply part 90 as a third gas supply part that supplies the inert gas into the unit. With such a configuration, the film of the workpiece W may be brought into contact with the inert gas also in the temperature adjustment unit U5. This makes it possible to reduce the time during which the workpiece W is exposed to the ambient atmosphere.

The coating developing apparatus 2 may further include the control device 100 as a control part that controls the contact period of the workpiece W in the gas contact part and the transfer of the workpiece W to the gas contact part. With such a configuration, the control device 100 may control the contact period of the workpiece W in the gas contact part and the transfer of the workpiece W. For example, the time during which the metal-containing resist film of each workpiece W is in contact with the ambient atmosphere may be shortened while adjusting the transfer route of a plurality of workpieces W, and the like.

At this time, the gas contact part may be the gas supply unit U6 as a gas processing unit configured to temporarily place the workpiece W in the chamber 20 as a predetermined housing and including the gas supply part 30 that supplies a gas into the housing. Further, the gas supply unit U6 may be provided in the interface block 6. At this time, the control device 100 may perform control to transfer the workpiece W to the gas supply unit U6 and bring the film into contact with the inert gas for a predetermined time in the gas supply unit U6. In such a configuration, the film may be brought into contact with the inert gas by transferring the workpiece W to the gas supply unit U6 using the control device 100.

The heat treatment unit U4 as a heat treatment part may include the hot plate 62 configured to heat the workpiece W, the temperature adjustment plate 51 configured to hold the workpiece W subjected to the heat treatment on the hot plate 62, and the gas supply part 58 as a second gas supply part configured to supply the inert gas. At this time, the control device 100 may perform control to bring the film of the workpiece W unloaded from the gas supply unit U6 into contact with the inert gas on the temperature adjustment plate 51 for a predetermined time. With such a configuration, the control device 10 may bring the film into contact with the inert gas while keeping the workpiece W on standby on the temperature adjustment plate 51.

The coating developing apparatus 2 may further include the temperature adjustment unit U5 configured to temporarily hold the workpiece W unloaded from the heat treatment unit U4 before carrying the workpiece W into the developing unit U3 as a developing process part. At this time, the temperature adjustment unit U5 may include the gas supply part 90 as a third gas supply part that supplies the inert gas into the unit. In an aspect, at this time, the control device 100 may perform control to bring the film of the workpiece W unloaded from the heat treatment unit U4 into contact with the inert gas in the temperature adjustment unit U5 for a predetermined time. With such a configuration, the film may be brought into contact with the inert gas by transferring the workpiece W to the temperature adjustment unit U5 using the control device 100.

Further, in an aspect, the inert gas may be a nitrogen gas. With such a configuration, it is possible to reduce the exposure of the substrate to the ambient atmosphere more inexpensively and reliably. The gas to be brought into contact with the workpiece W in the gas contact part does not need to have a purity of 100%, and may contain a component different from the inert gas. However, as described above, the moisture in the gas may possibly affect the line width (CD) of the film of the workpiece W. Therefore, the influence on the line width (CD) may be reduced by adjusting the moisture contained in the gas supplied from the gas contact part to fall within a desired range (e.g., 5% or less). Similarly, adjusting the oxygen component contained in the gas supplied in the gas contact part so as to be small is also effective in reducing the influence on the line width (CD). On the other hand, when the adjustment of the oxygen content is effective for controlling the line width (CD), a gas obtained by mixing a predetermined amount of oxygen component with an inert gas may be supplied to the workpiece W.

### [Modifications]

While various exemplary embodiments have been described above, various omissions, substitutions, and modifications may be made without being limited to the above-described exemplary embodiments. In addition, elements of different embodiments may be combined with each other to form other embodiments.

### (Modification of the Shape of the Gas Contact Part)

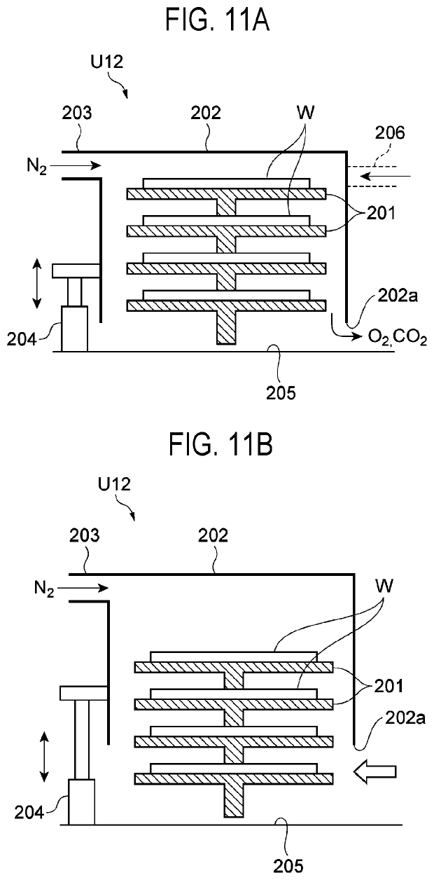

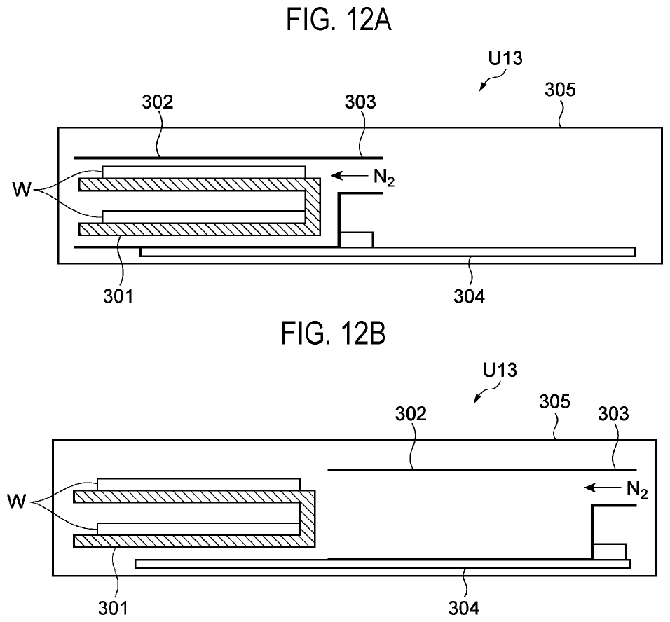

In the above-described embodiment, an exemplary embodiment was described in which the gas contact parts are realized in the gas supply unit U6, the heat treatment unit U4, and the temperature adjustment unit U5. Further, as an example of the configuration thereof, there has been described the configuration in which the inert gas is brought into contact with the workpiece W while holding one workpiece W. However, instead of such a configuration, a configuration in which a plurality of workpieces W are brought into contact with the inert gas at the same time may be adopted. As an example of such a configuration, two examples are illustrated with reference to FIGS. 11A and 11B, and FIGS. 12A and 12B. The modifications illustrated in FIGS. 11A and 11B, and FIGS. 12A and 12B may be applied to both the gas supply unit U6 and the temperature adjustment unit U5.

As a first example, FIGS. 11A and 11B illustrate configurations of a gas supply unit U12 as a gas contact part that supplies an inert gas from above. The gas supply unit U12 functioning as a gas contact part includes a substrate holding part 201 that holds a workpiece W, an enclosing part 202 that surrounds the upper side and the lateral side of the substrate holding part 201, and a gas supply port 203 that supplies an inert gas into the enclosing part 202 from above. A plurality of substrate holding parts 201 may be arranged in the vertical direction, so that a plurality of workpieces W may be held by the plurality of substrate holding parts 201. Further, the enclosing part 202 may be vertically drivable by a driving part 204. Moreover, the lower end of the enclosing part 202 may be spaced apart from the floor surface 205, and a space (gap) may be provided between the lower end 202a of the enclosing part 202 and the floor surface 205. The enclosing part 202 may be provided with a gas supply port 206 for supplying a gas different from the gas supplied by the gas supply port 203. In this case, the gas supplied from the gas supply port 206 includes, for example, oxygen.

At this time, as illustrated in FIG. 11A, the inert gas is supplied from the gas supply port 203 into the enclosing part 202, thereby pushing the internal atmosphere downward. When the inert gas is a nitrogen gas, oxygen or carbon dioxide in the atmosphere is pushed downward due to the difference in specific gravity, and is pushed outward from the gap between the lower end 202a and the floor surface 205. Therefore, the contact between the inert gas and the film of the workpiece W may be achieved even when the enclosing part 202 having a gap on the lower side thereof is used.

When moving the workpiece W, as illustrated in FIG. 11B, the enclosing part 202 is moved upward by the driving part 204. As a result, the gap between the lower end 202a and the floor surface 205 is enlarged so that the workpiece W may move. The substrate holding part 201 itself may be configured to be movable.

FIGS. 12A and 12B illustrate, as a second example, configurations of a gas supply unit U13 in which the shape of the enclosing part is changed. The gas supply unit U13 functioning as a gas contact part includes a substrate holding part 301 that holds a workpiece W, an enclosing part 302 that surrounds the upper side, the lower side, and a part of the lateral side of the substrate holding part 301, and a gas supply port 303 that supplies an inert gas into the enclosing part 302. The substrate holding part 301 may be capable of holding two workpieces W in the vertical direction. Moreover, the enclosing part 302 may be horizontally drivable by a driving part 304. In addition, the enclosing part 302 and the driving part 304 may be arranged inside a housing 305.

At this time, as illustrated in FIG. 12A, the inert gas is supplied from the gas supply port 303 of the enclosing part 302, thereby pushing the internal atmosphere outward from the side opening. Therefore, the contact between the inert gas and the film of the workpiece W may be achieved even when the enclosing part 302 having a gap on the lateral side thereof is used.

When moving the workpiece W, as illustrated in FIG. 12B, the enclosing part 302 is moved in the horizontal direction by the driving part 304 to a position where the enclosing part 302 does not overlap the substrate holding part 301. Thus, the workpiece W may be moved. Since the gas supply unit U13 may be made lower than the gas supply unit U12, it may be an effective configuration when the size of the space in the vertical direction is limited. Instead of moving the enclosing part 302, the substrate holding part 301 may be configured to be movable. Further, just like the gas supply unit U12, a gas supply port for supplying a gas different from the gas supplied through the gas supply port 303 may be separately provided.

### (Other Modifications)

In the above-described embodiment, an exemplary embodiment was described where the gas contact parts are realized in the gas supply unit U6, the heat treatment unit U4, and the temperature adjustment unit U5. However, the gas contact part may be realized only in some of the gas supply unit U6, the heat treatment unit U4, and the temperature adjustment unit U5. For example, a configuration in which only the gas supply unit U6 functions as a gas contact part may be adopted.

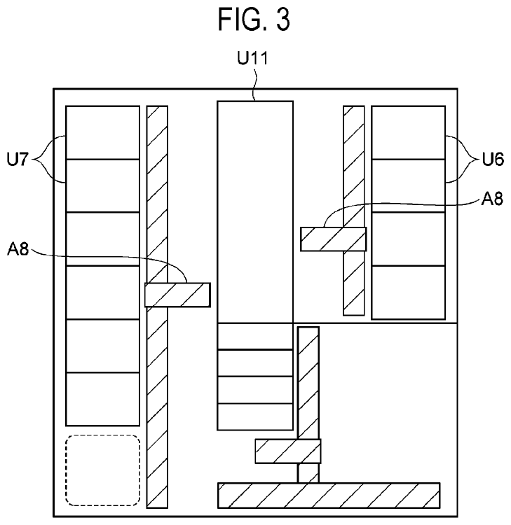

In the above-described embodiment, an exemplary embodiment was described where the gas supply unit U6 is used to bring the inert gas into contact with the workpiece W subjected to an exposing process. Unlike this configuration, the coating developing apparatus may further include a second gas contact part that brings the film of the workpiece W subjected to the processing by the film-forming process part and not subjected to the exposing process, i.e., the workpiece W before being loaded into the exposing apparatus 3, into contact with an inert gas. The configuration of the second gas contact part may be, for example, the same configuration as the gas supply unit U6 illustrated in FIG. 4. When the second gas contact part is arranged in the coating developing apparatus 2, for example, it is conceivable to arrange the second gas contact part in a part of the interface block 6 where the cleaning unit U7 illustrated in FIG. 2 or 3 is arranged.

In the above-described embodiment, the line width (CD) is affected by the contact of the film subjected to the exposing process with moisture and/or oxygen. However, the contact of the film not subjected to the exposing process with moisture and/or oxygen may also affect the linewidth of the film. That is, in the above-described embodiment, the post-exposure delay time (PED time) may possibly affect the line width (CD). However, the length of the pre-exposure delay time before the exposing process may also affect the line width (CD). Therefore, the line width of the metal-containing resist may be more stably adjusted by adopting the configuration in which the second gas contact part is arranged.

Moreover, when the second gas contact part is arranged, a separate configuration may be employed in place of or in addition to arranging the second gas contact part as a unit in the interface block 6 as described above. For example, after the metal-containing resist is coated on the workpiece W and before the pre-exposure heat treatment is performed, a unit or functional part as the second gas contact part may be provided. Moreover, not only the above-described location, just like the heat treatment unit U4, each module in the transfer path for the workpiece W may be configured to have a function of contacting the inert gas. As described above, the workpiece W is taken out from the carrier C of the coating developing apparatus 2 and transferred from the carrier block 4 to the processing block 5. Then, in the processing block 5, the formation of a metal-containing resist film and the pre-exposure heat treatment is performed. Thereafter, the workpiece W is transferred to the interface block 6 after performing the pre-exposure heat treatment, and is transferred from the interface block 6 to the exposing apparatus 3. Not only after forming the film, a function as the second gas contact part that brings the inert gas into contact with the workpiece W before being transferred to the exposing apparatus 3 may be provided as a unit or a functional part on the path of the workpiece W.

Furthermore, the above-described configuration in which the inert gas is brought into contact with the film on the workpiece W may also be applied to an apparatus other than the coating developing apparatus 2. For example, even in a coating apparatus that performs only a coating process on a workpiece W, a function corresponding to the above-described second gas contact part may be provided.

From the foregoing description, it will be appreciated that various embodiments of the present disclosure have been set forth herein for purposes of description, and that various changes may be made without departing from the scope and spirit of the present disclosure. Therefore, the various embodiments disclosed herein are not intended to be limitative, and the true scope and spirit are defined by the appended claims.

### (Modification of the Substrate Processing)

In the coating developing apparatus 2, a plurality of workpieces W are processed simultaneously. Therefore, the transfer plan is executed so that the workpiece W to be processed next is exposed to the inert gas in the gas contact part until the processing of the workpiece W in each unit is completed. Then, the transfer plan is executed so that the workpiece W to be processed next is loaded after each unit becomes ready to receive the workpiece W to be processed next.

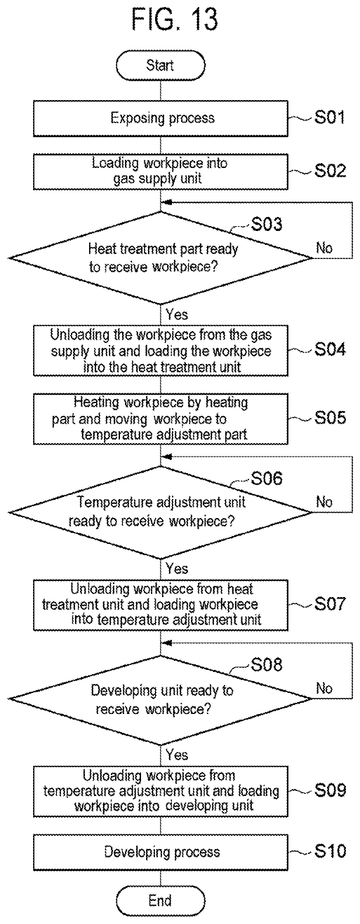

FIG. 13 is a flowchart illustrating another example of the substrate processing method. First, the control device 100 executes step S01. In step S01, the unit control part 106 executes an exposing process on the workpiece W based on the transfer plan stored in the operation command holding part 108.

Subsequently, the control device 100 executes step S02. In step S02, the transfer control part 104 controls the transfer device A8 so as to load the workpiece W subjected to the exposing process into the gas supply unit U6. In step S02, the unit control part 106 controls the gas supply unit U6 to open and close the chamber 20 (accommodation chamber) to accommodate the workpiece W in the chamber 20. At the same time, the unit control part 106 starts supplying a gas from the gas supply part 30 into the chamber 20. At this time, the gas supply unit U6 functions as a gas contact part. The unit control part 106 may cause the gas supply part to start supplying a gas into the chamber 20 before the workpiece W is accommodated in the chamber 20, thereby filling the chamber 20 with the inert gas in advance.

Subsequently, the control device 100 executes step S03. In step S03, the transfer control part 104 determines whether or not the heat treatment unit U4 is ready to receive the workpiece W. For example, the transfer control part 104 determines whether or not the heat treatment unit U4 is ready to receive the workpiece W based on the transfer history of the workpiece W, the status signal obtained from the heat treatment unit U4, or the like. As a result of the determination, when the heat treatment unit U4 is determined to be not ready to receive the workpiece (NO in S03), the transfer control part 104 controls the transfer device A8 so as not to unload the workpiece W from the gas supply unit U6. At this time, the workpiece W may be continuously exposed to the inert gas in the gas supply unit U6. In other words, the transfer control part 104 may cause the workpiece W to be kept on standby in the gas supply unit U6. Further, the case where the heat treatment unit U4 is not ready to receive the workpiece W may refer to, for example, a case where another workpiece W is being heat-treated in the heat treatment unit U4. With the above configuration, the workpiece W may be brought into contact with the inert gas in the gas supply unit U6 until the heat treatment for another workpiece W is completed. As a result, it is possible to reduce the time during which the workpiece W is kept on standby outside the unit and is in contact with moisture, oxygen, and/or carbon dioxide.

As a result of the determination, when the heat treatment unit U4 is ready to receive the workpiece W (YES in S03), the control device 100 executes step S04. In step S04, the transfer control part 104 controls the transfer device A8 so as to unload the workpiece W from the chamber 20 of the gas supply unit U6 and load the workpiece W into the heat treatment unit U4.

Subsequently, the control device 100 executes step S05. In step S05, the unit control part 106 controls the heat treatment unit U4 to heat the workpiece W on the hot plate 62 of the heating part 60 for a predetermined time, and then moves the workpiece W to the temperature adjustment plate 51 of the temperature adjustment part 50. In step S05, the unit control part 106 controls the heat treatment unit U4 to open and close the chamber 54 (second accommodation chamber) of the temperature adjustment part 50 to accommodate the workpiece W in the chamber 54. At the same time, the unit control part 106 may start supplying a gas from the gas supply part 58 (second gas supply part) into the chamber 54. At this time, the temperature adjustment part 50 in the heat treatment unit U4 may function as a gas contact part. The unit control part 106 may cause the gas supply part 58 to start supplying a gas into the chamber 54 before the workpiece W is accommodated in the chamber 54, thereby filling the chamber 54 with the inert gas in advance.

Subsequently, the control device 100 executes step S06. In step S06, the transfer control part 104 determines whether or not the temperature adjustment unit U5 is ready to receive the workpiece W. For example, the transfer control part 104 determines whether or not the temperature adjustment unit U5 is ready to receive the workpiece W based on the transfer history of the workpiece W, the status signal obtained from the temperature adjustment unit U5, or the like. As a result of the determination, when the temperature adjustment unit U5 is not ready to receive the workpiece W (NO in S06), the transfer control part 104 controls the transfer device A3 so as not to unload the workpiece W from the temperature adjustment part 50 of the heat treatment unit U4. In this case, the workpiece W may be continuously exposed to the inert gas inside the temperature adjustment part 50 of the heat treatment unit U4. In other words, the transfer control part 104 may cause the workpiece W to be kept on standby in the temperature adjustment part 50 of the heat treatment unit U4. Further, the case where the temperature adjustment unit U5 is not ready to receive the workpiece W may refer to, for example, a case where another workpiece W is being subjected to a temperature adjustment process in the temperature adjustment unit U5. With the above configuration, the workpiece W may be brought into contact with the inert gas in the temperature adjustment part 50 of the heat treatment unit U4 until the temperature adjustment process for another workpiece W is completed. As a result, it is possible to reduce the time during which the workpiece W is kept on standby outside the unit and is in contact with moisture, oxygen, and/or carbon dioxide.

As a result of the determination, when the temperature adjustment unit U5 is determined to be ready to receive the workpiece W (YES in S06), the control device 100 executes step S07. In step S07, the transfer control part 104 controls the transfer device A3 so as to unload the workpiece W from the chamber 54 of the temperature adjustment part 50 in the heat treatment unit U4 and load the workpiece W into the temperature adjustment unit U5. In step S07, the unit control part 106 controls the temperature adjustment unit U5 to open and close the chamber 80 of the temperature adjustment unit U5 to accommodate the workpiece W in the chamber 80. At the same time, the unit control part 106 may start supplying a gas from the gas supply part 90 (third gas supply part) into the chamber 80. At this time, the temperature adjustment unit U5 may function as a gas contact part. The unit control part 106 may cause the gas supply part 90 to start supplying a gas into the chamber 80 before the workpiece W is accommodated in the chamber 80, thereby filling the chamber 80 with the inert gas in advance.

Subsequently, the control device 100 executes step S08. In step S08, the transfer control part 104 determines whether or not the developing unit U3 is ready to receive the workpiece W. For example, the transfer control part 104 determines whether or not the developing unit U3 is ready to receive the workpiece W based on the transfer history of the workpiece W, the status signal obtained from the developing unit U3, or the like. As a result of the determination, when the developing unit U3 is determined to be not ready to receive the workpiece W (NO in S08), the transfer control part 104 controls the transfer device A3 so as not to unload the workpiece W from the temperature adjustment unit U5. In this case, the workpiece W may be continuously exposed to the inert gas in the temperature adjustment unit U5. In other words, the transfer control part 104 may cause the workpiece W to be kept on standby in the temperature adjustment unit U5. Further, the case where the developing unit U3 is not ready to receive the workpiece W may refer to, for example, a case where another workpiece W is being subjected to a developing process in the developing unit U3. With the above configuration, the workpiece W may be brought into contact with the inert gas in the temperature adjustment unit U5 until the developing process for another workpiece W is completed. As a result, it is possible to reduce the time during which the workpiece W is kept on standby outside the unit and is in contact with moisture, oxygen, and/or carbon dioxide.

As a result of the determination, when the developing unit U3 is ready to receive the workpiece W (YES in S08), the control device 100 executes step S09. In step S09, the transfer control part 104 controls the transfer device A3 so as to unload the workpiece W from the chamber 80 of the temperature adjustment unit U5 and load the workpiece W into the developing unit U3.

Finally, the control device 100 executes step S10. In step S10, the unit control part 106 controls the developing unit U3 to perform a developing process on the workpiece W. Thus, a series of substrate processing for the workpiece W is completed.

In a case in which the coating developing apparatus does not include the temperature adjustment unit U5, steps S06 and S07 may be omitted, and step S08 is executed after step S05. In step S09, the workpiece W is unloaded from the heat treatment unit U4.

Even when the coating developing apparatus includes the temperature adjustment unit U5, the transfer control part 104 may directly transfer some of the workpieces W from the heat treatment unit U4 to the developing unit U3 without going through the temperature adjustment unit U5. For example, when it becomes possible to load the workpiece W into the developing unit U3 before the next workpiece W waits for the loading into the heat treatment unit U4 in a state in which the workpiece W is arranged in the temperature adjustment part 50 of the heat treatment unit U4, the transfer control part 104 may directly transfer the workpiece W from the heat treatment unit U4 to the developing unit U3. By partially omitting the passage through the temperature adjustment unit U5 in this way, it is possible to alleviate the load on the transfer device A3.

In the above-described procedure, the transfer control part 104 may not control the transfer device A8 or A3 so as to transfer the workpiece W immediately even when each unit completes the processing of another workpiece W and is ready to receive the workpiece W. For example, it is assumed that the workpiece W is exposed to the inert gas in the chamber 54 of the temperature adjustment part 50 of the heat treatment unit U4, and the temperature adjustment process for another workpiece W is completed in the temperature adjustment unit U5. Even in this case, for example, in a case in which a further workpiece W to be processed next in the heat treatment unit U4 is not loaded into the gas supply unit U6, the workpiece W may be continuously exposed to the inert gas in the temperature adjustment part 50 of the heat treatment unit U4. Alternatively, when a sufficient amount of time is not elapsed for a further workpiece W to be processed in the gas supply unit U6, the workpiece W may continue to be exposed to the inert gas. By appropriately changing the standby time of the workpiece W in the temperature adjustment part 50, the gas supply unit U6, the temperature adjustment unit U5, or the like as described above, it is possible to disperse the load on the transfer device A3 in a chronological order.

### (First Modification of the Coating Developing Apparatus)

The configuration of the coating developing apparatus is not limited to the coating developing apparatus 2 according to the embodiment. In a coating developing apparatus according to a first modification, the shelf unit U11 provided in the interface block 6 may function as a gas contact part. In this case, for example, the shelf unit U11 is connected to the gas supply part 30. Then, the unit control part 106 controls the shelf unit U11 and the gas supply part 30 so that the inert gas is supplied from the gas supply part 30 into the plurality of cells of the shelf unit U1 1. When the shelf unit U11 functions as a gas contact part, the interface block 6 may not be provided with the gas supply unit U6.

### (Second Modification of the Coating Developing Apparatus)

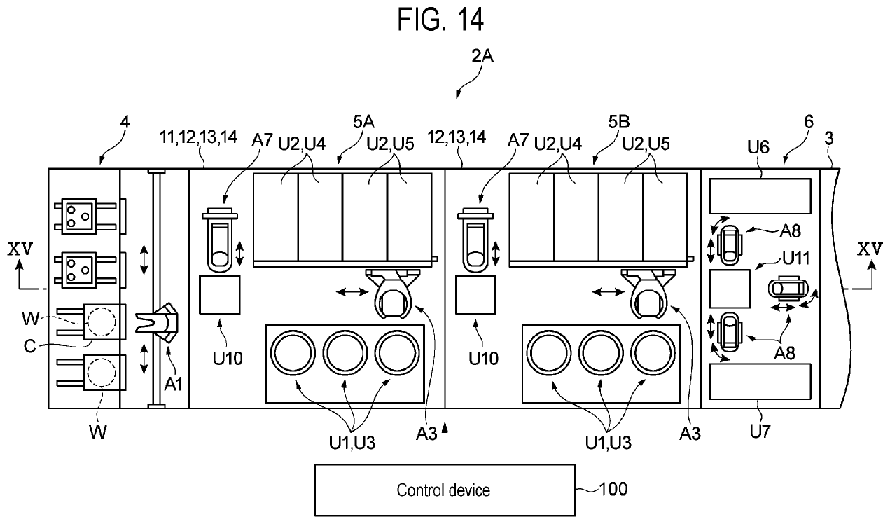

FIG. 14 is a schematic diagram illustrating a coating developing apparatus 2A according to a second modification. The coating developing apparatus 2A differs from the coating developing apparatus 2 according to the embodiment in that it includes a first processing block and a second processing block 5B, and is the same as the coating developing apparatus 2 in terms of other configurations. The first processing block 5A and the second processing block are arranged adjacent to each other. In the example of FIG. 14, the first processing block is arranged adjacent to the carrier block 4. The second processing block 5B is arranged adjacent to the interface block 6.

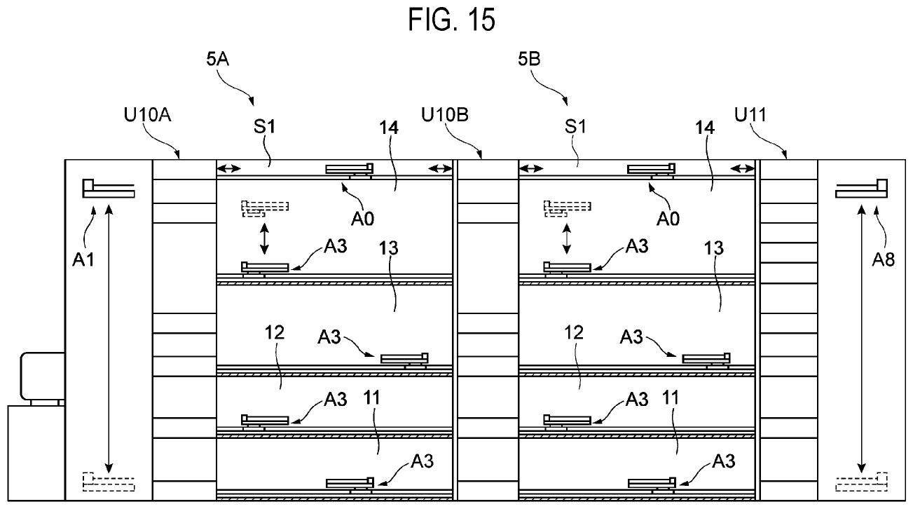

FIG. 15 illustrates a configuration of the coating developing apparatus 2A corresponding to an XV-XV line view. Each of the first processing block 5A and the second processing block differs from the processing block 5 in that it has a shuttle transfer path S1, and is the same as the processing block 5 in terms of other configurations. The shuttle transfer path S1 is arranged above the processing module 14 when the side of the processing module 11 is assumed to be a lower side and the side of the processing module 14 is assumed to be an upper side. A shuttle transfer device A0 is provided in the shuttle transfer path S1. In this regard, the shelf unit provided in the first processing block 5A is referred to as shelf unit U10A, and the shelf unit provided in the second processing block 5B is referred to as shelf unit U10B.

The shuttle transfer device A0 in the first processing block 5A transfers the workpiece W in both directions between the shelf unit U10A and the shelf unit U10B. In addition, the shuttle transfer device A0 in the second processing block 5B transfers the workpiece W in both directions between the shelf unit U10B and the shelf unit U11.

At least one of the shelf unit U10A, the shelf unit U10B, the shelf unit U11, the shuttle transfer path Si in the first processing block 5A, and the shuttle transfer path S1 in the second processing block 5B functions as a gas contact part. The shelf unit U10A, the shelf unit U10B, the shelf unit U11, the shuttle transfer path Si in the first processing block 5A, and the shuttle transfer path S1 in the second processing block 5B may be connected to an existing gas supply part. The existing gas supply part is, for example, the gas supply part 58 provided in the heat treatment unit U4. Alternatively, the shelf unit U10A, the shelf unit U10B, the shelf unit U11, the shuttle transfer path S1 in the first processing block 5A, and the shuttle transfer path S1 in the second processing block 5B may be connected to a newly-provided gas supply part. The unit control part 106 controls each shelf unit and the gas supply part connected to each shelf unit so as to supply an inert gas from the gas supply part into the plurality of cells of the shelf unit U10A, the shelf unit U10B, and the shelf unit U11. Further, the unit control part 106 controls each shuttle transfer path Si and the gas supply part connected to each shuttle transfer path S1 so that the inert gas is supplied from the gas supply part into the shuttle transfer path S1 in the first processing block 5A and the second processing block 5B.

Some patterns will be described below in which at least one of the shelf unit U10A, the shelf unit U10B, the shelf unit U11, the shuttle transfer path S1 in the first processing block 5A, and the shuttle transfer path Si in the second processing block 5B functions as a gas contact part.

As a first pattern, a case where a heat treatment is performed in the second processing block 5B and a developing process is performed in the first processing block 5A will be described. The transfer control part 104 controls the transfer device A8 so as to load the workpiece W subjected to the exposing process into the shelf unit U11. The shelf unit U11 may store the workpiece W until the heat treatment unit U4 in the second processing block 5B becomes ready to perform a heat treatment. At this time, the shelf unit U11 functions as a gas contact part, and the workpiece W is exposed to the inert gas atmosphere. Subsequently, when the heat treatment unit U4 in the second processing block 5B becomes ready to perform a heat treatment, the transfer control part 104 controls the transfer device A3 in the second processing block 5B so as to unload the workpiece W from the shelf unit U11 and then load the workpiece W into the heat treatment unit U4. The temperature adjustment part 50 provided in the heat treatment unit U4 of the second processing block 5B functions as a gas contact part, and the workpiece W is exposed to an inert gas atmosphere. Subsequently, the transfer control part 104 controls the transfer device A3 in the second processing block 5B so as to unload the heat-treated workpiece W from the heat treatment unit U4 and then loads the heat-treated workpiece W into the shelf unit U10B. The shelf unit U1 OB may store the workpiece W until the developing unit U3 in the first processing block 5A becomes ready to perform a developing process. At this time, the shelf unit U10B functions as a gas contact part, and the workpiece W is exposed to an inert gas atmosphere. Subsequently, when the developing unit U3 in the first processing block 5A becomes ready to perform a developing process, the transfer control part 104 controls the transfer device A3 in the first processing block 5A so as to unload the workpiece W from the shelf unit U10B and then load the workpiece W into the developing unit U3. Subsequently, the transfer control part 104 controls the transfer device A3 in the first processing block 5A so as to unload the developed workpiece W from the developing unit U3 and then load the developed workpiece W into the shelf unit U10A. The shelf unit U10A may store the workpiece W until the preparation for unloading the workpiece W to the outside is completed. At this time, the shelf unit U10A functions as a gas contact part, and the workpiece W is exposed to an inert gas atmosphere.

As a second pattern, a case where a heat treatment and a developing process are performed in the second processing block 5B will be described. The process until the workpiece W is heat-treated in the heat treatment unit U4 of the second processing block 5B is the same as that in the first pattern. The transfer control part 104 controls the transfer device A3 in the second processing block 5B so as to unload the heat-treated workpiece W from the heat treatment unit U4 and then load the heat-treated workpiece W into the temperature adjustment unit U5 in the second processing block 5B. The temperature control unit U5 functions as a gas contact part, and the workpiece W is exposed to an inert gas atmosphere. Subsequently, the transfer control part 104 controls the transfer device A3 in the second processing block 5B so as to unload the temperature-adjusted workpiece W from the temperature adjustment unit U5 and then load the temperature-adjusted workpiece W into the developing unit U3 in the second processing block 5B. The transfer control part 104 controls the transfer device A3 in the second processing block 5B so as to unload the workpiece W subjected to the developing process from the developing unit U3 and then load the workpiece W into the shelf unit U10B. At this time, the shelf unit U10B functions as a gas contact part, and the workpiece W is exposed to an inert gas atmosphere. Subsequently, the transfer control part 104 controls the shuttle transfer device A0 in the first processing block 5A to unload the workpiece W from the shelf unit U10B and load the workpiece W into the shelf unit U10A. At this time, the shuttle transfer path 51 in the first processing block 5A functions as a gas contact part, and the workpiece W is exposed to an inert gas atmosphere. The shelf unit U10A may store the workpiece W until the preparation for unloading the workpiece W to the outside is completed. At this time, the shelf unit U10A functions as a gas contact part, and the workpiece W is exposed to an inert gas atmosphere.

As a third pattern, a case where a heat treatment and a developing process are performed in the first processing block 5A will be described. The transfer control part 104 controls the transfer device A8 so as to load the workpiece W subjected to an exposing process into the shelf unit U11. At this time, the shelf unit U11 functions as a gas contact part, and the workpiece W is exposed to an inert gas atmosphere. Subsequently, the transfer control part 104 controls the shuttle transfer device A0 in the second processing block 5B to unload the workpiece W from the shelf unit U11 and load the workpiece W into the shelf unit U10B. At this time, the shuttle transfer path S1 in the second processing block 5B functions as a gas contact part, and the workpiece W is exposed to an inert gas atmosphere. The shelf unit U10B may store the workpiece W until the heat treatment unit U4 in the first processing block 5A becomes ready to perform a heat treatment. At this time, the shelf unit U10B functions as a gas contact part, and the workpiece W is exposed to an inert gas atmosphere. Subsequently, when the heat treatment unit U4 in the first processing block 5A becomes ready to perform a heat treatment, the transfer control part 104 controls the transfer device A3 in the first processing block 5A so as to unload the workpiece W from the shelf unit U10B and then load the workpiece W into the heat treatment unit U4. The temperature adjustment part 50 provided in the heat treatment unit U4 of the first processing block 5A functions as a gas contact part, and the workpiece W is exposed to an inert gas atmosphere. Subsequently, the transfer control part 104 controls the transfer device A3 in the first processing block 5A so as to unload the heat-treated workpiece W from the heat treatment unit U4 and then load the workpiece W into the temperature adjustment unit U5 in the first processing block 5A. The temperature control unit U5 functions as a gas contact part, and the workpiece W is exposed to an inert gas atmosphere. Subsequently, the transfer control part 104 controls the transfer device A3 in the first processing block 5A so as to unload the temperature-adjusted workpiece W from the temperature adjustment unit U5 and then load the workpiece W into the developing unit U3 of the first processing block 5A. Subsequently, the transfer control part 104 controls the transfer device A3 in the first processing block 5A so as to unload the workpiece W subjected to the developing process from the developing unit U3 and then load the workpiece W into the shelf unit U10A. The shelf unit U10A may store the workpiece W until the preparation for unloading the workpiece W to the outside is completed. At this time, the shelf unit U10A functions as a gas contact part, and the workpiece W is exposed to an inert gas atmosphere.

As a fourth pattern, a case where the workpiece W is heat-treated in the second processing block 5B and then unloaded to the outside will be described. The process until the heat-treated workpiece W is loaded into the shelf unit U1 OB is the same as the process in the first pattern. The transfer control part 104 controls the shuttle transfer device A0 in the first processing block 5A so as to unload the workpiece W from the shelf unit U1 OB and load the workpiece W into the shelf unit U10A. At this time, the shuttle transfer path 51 in the first processing block 5A functions as a gas contact part, and the workpiece W is exposed to an inert gas atmosphere. The shelf unit U10A may store the workpiece W until the preparation for unloading the workpiece W to the outside is completed. At this time, the shelf unit U10A functions as a gas contact part, and the workpiece W is exposed to an inert gas atmosphere.

As a fifth pattern, a case where the workpiece W subjected to an exposing process is unloaded to the outside will be described. The transfer control part 104 controls the transfer device A8 so as to load the workpiece W subjected to the exposing process into the shelf unit U11. At this time, the shelf unit U11 functions as a gas contact part, and the workpiece W is exposed to an inert gas atmosphere. Subsequently, the transfer control part 104 controls the shuttle transfer device A0 in the second processing block 5B so as to unload the workpiece W from the shelf unit U11 and load the workpiece W into the shelf unit U10B. At this time, the shuttle transfer path S1 in the second processing block 5B functions as a gas contact part, and the workpiece W is exposed to an inert gas atmosphere. In addition, the shelf unit U10B functions as a gas contact part, and the workpiece W is exposed to an inert gas atmosphere. Subsequently, the transfer control part 104 controls the shuttle transfer device A0 in the first processing block 5A so as to unload the workpiece W from the shelf unit U10B and load the workpiece W into the shelf unit U10A. At this time, the shuttle transfer path Si in the first processing block 5A functions as a gas contact part, and the workpiece W is exposed to an inert gas atmosphere. The shelf unit U10A may store the workpiece W until the preparation for unloading the workpiece W to the outside is completed. At this time, the shelf unit U10A functions as a gas contact part, and the workpiece W is exposed to an inert gas atmosphere.

At least one of the shelf unit U10A, the shelf unit U10B, the shelf unit U11, the shuttle transfer path S1 in the first processing block 5A, and the shuttle transfer path S1 in the second processing block 5B functions as a gas contact part. As a result, it is possible to ensure a longer time for the film of the workpiece W to be kept in contact with the inert gas. This makes it easier to suppress the reaction of the metal-containing resist from the exposing process to the start of the developing process.

In each of the first to fifth patterns, the shelf unit U1 OB functions as a gas contact part. The shelf unit U10B may include a mechanism for adjusting the temperature of the workpiece W to a predetermined temperature when the workpiece W is exposed to the inert gas atmosphere.

In each of the first to fifth patterns, the transfer control part 104 may load the workpiece W into the shelf unit 10A instead of the shelf unit 10B. For example, in a case in which all the cells of the shelf unit 10B are filled with other workpieces W when the workpiece W is loaded into the shelf unit U10B, the transfer control part 104 may load the workpiece W into the shelf unit 10A. For example, in the first pattern, the transfer control part 104 may control the transfer device A3 in the first processing block 5A so as to unload the heat-treated workpiece W from the heat treatment unit U4 of the second processing block 5B and then load the workpiece W into the shelf unit U10A via the shelf unit U10B. Alternatively, the transfer device A3 in the first processing block 5A may be controlled. Alternatively, the transfer control part 104 may control the shuttle transfer device A0 in the first processing block 5A so as to load the workpiece W into the shelf unit U10A via the shelf unit U1 OB. Then, the shelf unit U10A may store the workpiece W until the developing unit U3 in the first processing block 5A becomes ready to perform a developing process. At this time, the shelf unit U10A may include a mechanism for adjusting the temperature of the workpiece W to a predetermined temperature.

In each of the first to fifth patterns, the shelf unit U10A may store the workpiece W not only until the preparations for unloading the workpiece W to the outside are completed, but also until the workpiece W is subjected to a certain process again. For example, the shelf unit U10A may store the workpiece W until it becomes possible to transfer the workpiece W to the next transfer destination. The next transfer destination may be, for example, the carrier block 4. The next transfer destination may be, for example, another processing unit provided in the coating developing apparatus 2. In another processing unit, for example, the workpiece W subjected to the developing process may be subjected to a liquid processing process, a heat treatment, a polishing process, or the like. The place where the workpiece W is stored is not limited to the shelf unit U10A, but may be at least one of the shelf unit U10B, the shelf unit U11, the shuttle transfer path Si in the first processing block 5A, and the shuttle transfer path S1 in the second processing block 5B. At this time, the place where the workpiece W is stored functions as a gas contact part. In this case, in the first to third patterns, the workpiece W subjected to the developing process is exposed to an inert gas in at least one of the shelf unit U10A, the shelf unit U10B, the shelf unit U11, the shuttle transfer path S1 in the first processing block 5A, and the shuttle transfer path Si in the second processing block 5B.

According to the present disclosure in some embodiments, it is possible to provide a technique for minimizing the time during which a metal-containing resist film formed on a substrate is in contact with the ambient atmosphere.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus for processing a substrate including a metal-containing resist film, comprising:
a heat treatment part configured to perform a heat treatment on the substrate having the film subjected to an exposing process;
a developing process part configured to perform a developing process on the film of the substrate subjected to the heat treatment; and
a gas contact part configured to bring the film into contact with an inert gas during a period after the exposing process and before the developing process.

2. The substrate processing apparatus of claim 1, wherein the gas contact part is a gas processing unit configured to temporarily place the substrate inside a predetermined housing and includes a gas supply part configured to supply a gas into the housing, and is provided in an interface block.

3. The substrate processing apparatus of claim 1, wherein the heat treatment part includes a hot plate configured to heat the substrate, and a temperature adjustment plate configured to hold the substrate subjected to the heat treatment on the hot plate, and
the gas contact part includes a second gas supply part configured to supply the inert gas so that the temperature adjustment plate of the heat treatment part and the film of the substrate on the temperature adjustment plate are in contact with the inert gas.

4. The substrate processing apparatus of claim 3, wherein the gas contact part further includes a chamber configured to surround the temperature adjustment plate so that the inert gas supplied from the second gas supply part is brought into contact with the film.

5. The substrate processing apparatus of claim 1, wherein the gas contact part is a temperature adjustment unit configured to temporarily hold the substrate unloaded from the heat treatment part before the substrate is loaded into the developing process part, and
the gas contact part includes a third gas supply part configured to supply the inert gas into the temperature adjustment unit.

6. The substrate processing apparatus of claim 1, further comprising:
a control part configured to control the period during which the film of the substrate is brought into contact with the inert gas in the gas contact part and a transfer of the substrate to the gas contact part.

7. The substrate processing apparatus of claim 6, wherein the gas contact part is a gas processing unit configured to temporarily place the substrate in a predetermined housing and includes a gas supply part configured to supply the gas into the housing,
the gas contact part is provided in an interface block, and
the control part performs a control to transfer the substrate to the gas processing unit and to bring the film into contact with the inert gas in the gas processing unit for a predetermined time.

8. The substrate processing apparatus of claim 7, wherein the heat treatment part includes a hot plate configured to heat the substrate, a temperature adjustment plate configured to hold the substrate subjected to the heat treatment on the hot plate, and a second gas supply part configured to supply the inert gas so that the film of the substrate on the temperature adjustment plate is brought into contact with the inert gas, and
the control part is configured to perform a control to bring the film of the substrate unloaded from the gas processing unit into contact with the inert gas for the predetermined time on the temperature adjustment plate of the heat treatment part.

9. The substrate processing apparatus of claim 8, further comprising:
a temperature adjustment unit configured to temporarily hold the substrate unloaded from the heat treatment part before loading the substrate into the developing process part,
wherein the temperature adjustment unit includes a third gas supply part configured to supply the inert gas into the temperature adjustment unit, and
the control part is configured to perform a control to bring the film of the substrate unloaded from the heat treatment part into contact with the inert gas for the predetermined time in the temperature adjustment unit.

10. The substrate processing apparatus of claim 1, wherein the gas contact part includes a substrate holding part configured to hold the substrate, an enclosing part configured to surround an upper side and a lateral side of the substrate holding part, and a gas supply port configured to supply the inert gas into the enclosing part from above the enclosing part, and
the gas contact part is configured to supply the inert gas into the enclosing part to push an internal atmosphere downward so that the inert gas into is brought into contact with the substrate held by the substrate holding part.

11. The substrate processing apparatus of claim 1, wherein the gas contact part includes a substrate holding part configured to hold the substrate, an enclosing part configured to surround upper and lower sides and a portion of a lateral side of the substrate holding part, and a gas supply port configured to supply the inert gas into the enclosing part, and
the gas contact part is configured to supply the inert gas into the enclosing part to push an internal atmosphere to the lateral side which is open, so that the inert gas is brought into contact with the substrate held by the substrate holding part.

12. The substrate processing apparatus of claim 1, wherein the inert gas is a nitrogen gas.

13. The substrate processing apparatus of claim 1, further comprising:
a second gas contact part configured to bring the film into contact with the inert gas during a period after a process is performed by a film-forming process part configured to form a metal-containing resist film on the substrate and before the exposing process.

14. The substrate processing apparatus of claim 1, further comprising:
a transfer device configured to transfer the substrate; and
a control part configured to control the transfer device,
wherein the gas contact part includes an accommodation chamber provided in an interface block to accommodate the substrate subjected to the exposing process, and a gas supply part configured to supply a gas into the accommodation chamber, and
the control part is configured to control the transfer device so as to unload the substrate from the accommodation chamber and load the substrate into the heat treatment part after the heat treatment part becomes ready to receive the substrate.

15. The substrate processing apparatus of claim 14, further comprising:
a temperature adjustment unit configured to accommodate the substrate unloaded from the heat treatment part and perform a temperature adjustment process on the substrate,
wherein the heat treatment part includes a hot plate configured to heat the substrate,
the gas contact part further includes a second accommodation chamber provided in the heat treatment part so as to accommodate the substrate subjected to a heat treatment on the hot plate, and a second gas supply part configured to supply the inert gas into the second accommodation chamber, and
the control part is configured to control the transfer device so as to unload the substrate from the second accommodation chamber and load the substrate into the temperature adjustment unit after the temperature adjustment unit becomes ready to receive the substrate.

16. The substrate processing apparatus of claim 15, wherein the gas contact part further includes a third gas supply part configured to supply the inert gas into the temperature adjustment unit, and
the control part is configured to control the transfer device so as to unload the substrate from the temperature adjustment unit and load the substrate into the developing process part after the developing process part becomes ready to receive the substrate.

17. The substrate processing apparatus of claim 14, wherein the heat treatment part includes a hot plate configured to heat the substrate,
the gas contact part includes a second accommodation chamber provided in the heat treatment part so as to accommodate the substrate subjected to the heat treatment on the hot plate, and a second gas supply part configured to supply the inert gas into the second accommodation part, and
the control part is configured to control the transfer device so as to unload the substrate from the second accommodation chamber and load the substrate into the developing process part after the developing process part becomes ready to receive the substrate.

18. A substrate processing method, comprising:
forming a metal-containing resist film on a substrate;
performing a heat treatment on the substrate having the film subjected to an exposing process;
performing a developing process on the film of the substrate subjected to the heat treatment; and
bringing the film into contact with an inert gas during a period after the exposing process and before the developing process.

19. A non-transitory computer-readable recording medium that records a substrate processing program for causing a computer to execute a substrate processing, the substrate processing program comprising:
forming a metal-containing resist film on a substrate;
performing a heat treatment on the substrate having the film subjected to an exposing process;
performing a developing process on the film of the substrate subjected to the heat treatment; and
bringing the film into contact with an inert gas during a period after the exposing process and before the developing process.
